(19) United States
(12) Patent Application Publication
(10) Pub. No.: US 2026/0366786 A1
(43) Pub. Date: Nov. 19, 2026

(54) DATA CENTER COOLING SYSTEM WITH PUMP FILTRATION SYSTEM

(71) Applicant: Tyco Fire & Security GmbH, Neuhausen am Rheinfall (CH)

(72) Inventor: Bryson Lee Sheaffer, Mechanicsburg, PA (US)

(21) Appl. No.: 19/677,844

(22) Filed: May 14, 2026

Related U.S. Application Data
(60) Provisional application No. 63/807,382, filed on May 16, 2025.

(51) Int. Cl. F25B 43/00; H05K 7/20

(52) U.S. Cl. CPC F25B 43/003; H05K 7/20327; H05K 7/208

(57) ABSTRACT

A data center cooling system includes a condenser configured to output a working fluid in a liquid form. The data center cooling system also includes a pump filtration system. The pump filtration system includes a casing, an inlet configured to receive the working fluid in the liquid form into the casing, a filter membrane disposed in the casing, a liquid passage between the casing and the filter membrane, an impeller, and a motor. The motor is configured to turn the impeller to bias the working fluid in the liquid form through the filter membrane to provide the working fluid in a filtered liquid form into the liquid passage. The pump filtration system also includes an outlet configured to output the working fluid in the filtered liquid form from the liquid passage.

### CROSS-REFERENCE TO RELATED APPLICATIONS

This application claims priority from and the benefit of U.S. Provisional Patent Application No. 63/807,382, entitled “SUBCOOLED LIQUID SEPARATOR SYSTEM INCLUDING CENTRIFUGAL CONTAMINANT PARTICLE ACCELERATION SECTION, PARALLEL FINE PARTICLE PUMP, AND FILTRATION FOR DATA CENTER,” filed on May 16, 2025, which are hereby incorporated by reference in their entireties for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Heating, ventilation, air conditioning, and refrigeration (HVAC&R) systems, such as chiller systems (e.g., vapor compression systems), utilize a working fluid (e.g., a refrigerant) that changes phases between vapor, liquid, and combinations thereof in response to exposure to different temperatures and pressures within components of the chiller system. HVAC&R systems may include a compressor for circulating a working fluid (e.g., refrigerant) along a working fluid circuit and through heat exchangers of the HVAC&R system. For example, the HVAC&R system may include a first heat exchanger configured to receive the working fluid and a conditioning fluid to place the working fluid in the heat exchange relationship with the conditioning fluid. The conditioning fluid may be directed from the first heat exchanger to other equipment, such as air handlers, to condition other fluids, such as air or water. The HVAC&R system may also include a second heat exchanger configured to receive the working fluid and a cooling fluid to place the working fluid in the heat exchange relationship with the cooling fluid. In some embodiments, the cooling fluid may be water. Alternatively, the cooling fluid may be another fluid, such as air. Unfortunately, existing HVAC&R system configurations are susceptible to various drawbacks, such as limited heat transfer efficiency, incompatibility with certain heating or cooling loads, and so forth.

Further to the points above, data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant to the racks to draw heat directly from the heat-generating equipment or use a combination of air and liquid cooling. As data centers expand to support the rapid growth of cloud computing, artificial intelligence, and other modern applications having high computing loads and power densities, data centers need effective, energy-efficient cooling solutions that serve these applications while minimizing environmental impact.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a data center cooling system includes a condenser configured to output a working fluid in a liquid form. The data center cooling system also includes a pump filtration system. The pump filtration system includes a casing, an inlet configured to receive the working fluid in the liquid form into the casing, a filter membrane disposed in the casing, a liquid passage between the casing and the filter membrane, an impeller, and a motor. The motor is configured to turn the impeller to bias the working fluid in the liquid form through the filter membrane to provide the working fluid in a filtered liquid form into the liquid passage. The pump filtration system also includes an outlet configured to output the working fluid in the filtered liquid form from the liquid passage.

In another embodiment, a pump filtration system for a data center cooling system includes an annular casing, an inlet configured to receive a working fluid in a liquid form into the annular casing, an annular filter membrane disposed in the annular casing, an annular outer liquid passage between the annular casing and the annular filter membrane, an impeller comprising an annular body disposed radially inward from the annular filter membrane, and a motor. The motor is configured to turn the impeller to bias the working fluid in the liquid form through the annular filter membrane to provide the working fluid in a filtered liquid form into the annular outer liquid passage. The pump filtration system also includes an outlet configured to output the working fluid in the filtered liquid form from the annular outer liquid passage.

In still another embodiment, a method of operating a data center cooling system includes receiving a working fluid in a liquid form into a central cavity defined by a casing of a pump filtration system of the data center cooling system. The method also includes rotating an impeller of the pump filtration system via a motor of the pump filtration system to bias the working fluid in the liquid form from the central cavity and through a filter membrane disposed in the casing. The method also includes removing contaminants from the working fluid in the liquid form via the filter membrane to provide the working fluid in a filtered liquid form. The method also includes receiving the working fluid in the filtered liquid form from the filter membrane into a liquid passage within the casing. The method also includes outputting the working fluid in the filtered liquid form from the liquid passage in the casing to an area outside of the casing.

### BRIEF DESCRIPTION OF THE DRAWINGS

Various aspects of this disclosure may be better understood upon reading the following detailed description and upon reference to the drawings in which:

FIG. 1 is a perspective view of an embodiment of a data center room including racks served by a data center cooling system, in accordance with an aspect of the present disclosure;

FIG. 2 is a block diagram of an embodiment of a data center cooling system, such as the data center cooling system of FIG. 1, in accordance with an aspect of the present disclosure;

FIG. 3 is a block diagram of an embodiment of a rack of a data center room, such as the data center room of FIG. 1, in greater detail, in accordance with an aspect of the present disclosure;

FIG. 4 is a perspective view of an embodiment of a server tray which can be installed in the racks of a data center room, such as the data center room of FIG. 1, in accordance with an aspect of the present disclosure;

FIG. 5 is a block diagram of an embodiment of a liquid cooling circuit which can be used in a data center cooling system, such as the data center cooling system of FIG. 1, in accordance with an aspect of the present disclosure;

FIG. 6 is a block diagram of an embodiment of an air cooling circuit which can be used in a data center cooling system, such as the data center cooling system of FIG. 1, in accordance with an aspect of the present disclosure;

FIG. 7 is a schematic of an embodiment of an HVAC&R system including a chiller system configured to provide cooling to electronic equipment, in accordance with an aspect of the present disclosure;

FIG. 8 is a schematic of an embodiment of a data center cooling system including a working fluid circuit, a pump filtration system, and a separator, where the pump filtration system is configured to filter (e.g., purify) a working fluid corresponding to the working fluid circuit, and the separator is configured to manage various phases and/or forms of the working fluid, in accordance with an aspect of the present disclosure;

FIG. 9 is a cross-sectional schematic of an embodiment of a pump filtration system for a data center cooling system, such as the data center cooling system of FIG. 8, in accordance with an aspect of the present disclosure;

FIG. 10 is a perspective view of an embodiment of a spiral volute of a pump filtration system, such as the pump filtration system of FIG. 9, for a data center cooling system, in accordance with an aspect of the present disclosure;

FIG. 11 is a schematic of an embodiment of shapes of a first end and a second end of a spiral volute, such as the spiral volute of FIG. 10, for a pump filtration of a data center cooling system, in accordance with an aspect of the present disclosure;

FIG. 12 is perspective view of an embodiment of a portion of a pump filtration system, such as the pump filtration system of FIG. 9, including a motor, an impeller, and a filter membrane of a pump filtration system, such as the pump filtration system of FIG. 9, for a data center cooling system, in accordance with an aspect of the present disclosure;

FIG. 13 is a perspective view of an embodiment of a portion of a pump filtration system, such as the pump filtration system of FIG. 9, including a wall, a ring, and blades of an impeller coupled to the wall or the ring, for a data center cooling system, in accordance with an aspect of the present disclosure; and

FIG. 14 is a process flow diagram illustrating an embodiment of a method of operating a data center cooling system including a pump filtration system, in accordance with an aspect of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/- 5%, within +/- 4%, within +/- 3%, within +/- 2%, within +/- 1%, or even closer, of the given value. Similarly, when a given feature is described as being “substantially parallel” to another feature, “generally perpendicular” to another feature, and so forth, this is intended to convey that the given feature is within +/- 5%, within +/- 4%, within +/- 3%, within +/- 2%, within +/- 1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

A heating, ventilation, air conditioning, and refrigeration (HVAC&R) system (e.g., chiller system) may be implemented to thermally regulate a space within a building, home, or other suitable structure. As used herein, an HVAC&R system may include any number of components configured to enable regulation of one or more parameters related to climate characteristics, such as temperature, humidity, air flow, pressure, air quality, and so forth. For example, an “HVAC&R system“ as used herein may be defined as a system configured to perform operations including one or more of heating, cooling, ventilation, dehumidification, pressurization, refrigeration, filtration, or any combination thereof. Indeed, certain HVAC&R systems incorporating the present techniques may be configured to perform certain operations (e.g., cooling) but not others (e.g., heating). Components or parts of an “HVAC&R system“ may include, but are not limited to, all, some of, or individual parts such as a heat exchanger, a fluid flow control device, such as a valve, a sensor configured to detect a climate characteristic or operating parameter, a filter, a control device configured to regulate operation of an HVAC&R system component, a component configured to enable regulation of one or more climate characteristics, or a combination thereof. The embodiments described herein may be utilized in a variety of applications to control climate characteristics, such as residential, commercial, industrial, transportation, or other applications where climate control is desired.

One such HVAC&R system includes a vapor compression system (e.g., vapor compression circuit) that transfers thermal energy between a working fluid (e.g., refrigerant) and a fluid to be conditioned, such as water, air, or another suitable fluid. The vapor compression system may include one or more heat exchangers, such as a condenser and an evaporator, that are fluidly coupled to one another via a working fluid circuit (e.g., refrigerant circuit, one or more conduits). The vapor compression system may also include a compressor configured to circulate the working fluid through the working fluid circuit and thereby enable the transfer of thermal energy between the condenser and the evaporator and respective fluids directed through the condenser and the evaporator.

In some applications, the HVAC&R system may be or include a chiller system configured to condition a conditioning fluid (e.g., water) that is directed to downstream equipment, such as air handlers, computer equipment, heat exchangers, and/or other components configured to utilize the conditioning fluid to cool a conditioned space, another device or component (e.g., computer system, computer server, electronic equipment), or both. To this end, the chiller system may include an evaporator configured to transfer heat from the conditioning fluid to a working fluid circulated through the chiller system. The chiller system may also include a condenser configured to transfer heat from the working fluid to a cooling fluid. In some applications, the cooling fluid may be water (e.g., water-cooled chiller). Alternatively, the cooling fluid may be air (e.g., air-cooled chiller). In yet further implementations, combinations of air and water may be used as the cooling fluid for the chiller system.

In some implementations, HVAC&R systems, such as chiller systems, dry coolers, and/or cooling towers, are utilized to cool electronic equipment. For example, electronic equipment, such as computers, servers, storage devices, network equipment, power supplies, computing systems, and/or information technology (IT) hardware or infrastructure, may generate substantial amounts of heat during operation. In order to facilitate proper operation of such electronic equipment, the generated heat should be transferred and/or rejected to another suitable location or environment in order to maintain operating temperatures of the electronic equipment below relevant threshold temperatures. It will be appreciated that some facilities, such as data centers, may house considerable amounts of electronic equipment that generate heat in a relatively small area. Accordingly, chiller systems may be implemented, along with other cooling system components, to enable rejection of heat generated by such electronic equipment.

In some implementations, the chiller systems may operate to cool a fluid that is placed in a heat exchange relationship with the electronic equipment. For example, some cooling systems may include coolant distribution units (CDUs) that include a heat exchanger configured to transfer heat between a conditioning fluid generated (e.g., cooled) by the chiller system and a coolant that is placed in a heat exchange relationship with the electronic equipment. The conditioning fluid cooled by the chiller system may be a flow of water (e.g., facility water) supplied or provided by a facility housing the electronic equipment (e.g., data center), and the coolant may be another flow of water (e.g., technical water, IT water) suitable for placing in a heat exchange relationship with the electronic equipment. The flow of water cooled by the chiller system may not be suitable for placing in a heat exchange relationship with the electronic equipment. Therefore, the heat exchanger of the CDU may isolate the conditioning fluid from the electronic equipment.

Additionally or alternatively, some cooling systems may include a chiller system having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment. In other embodiments, the chiller system may be configured to cool the working fluid and direct the working fluid to the electronic equipment to place the working fluid in a heat exchange relationship with the electronic equipment, such as via a chilled plate, a tube, a flow path, a channel, a vessel, and/or immersion cooling techniques. In such embodiments, the cooling system may or may not include a conditioning fluid circuit configured to place a conditioning fluid in a heat exchange relationship with the electronic equipment.

Additionally or alternatively, some cooling systems in accordance with the present disclosure may employ a working fluid circuit that directly interfaces with one or more racks, also referred to as cabinets, of a data center. For example, the working fluid circuit may circulate a working fluid of the cooling system to computer equipment disposed in (or otherwise integrated with) the one or more racks, to one or more cold plates associated with the computer equipment, or both. In certain such embodiments, the computer equipment and/or the cold plate(s) may operate as an evaporator of the cooling system. For example, the working fluid may extract heat from the computer equipment and/or the cold plate(s) which, in certain embodiments, causes the working fluid to evaporate to a vapor phase. The working fluid may be condensed to a liquid phase by a condenser interfacing with the working fluid circuit of the data center in such embodiments.

The above-described HVAC&R systems, cooling systems, and/or data center cooling systems of a data center are merely examples, as other types of systems are also possible in accordance with the present disclosure. In certain embodiments of a data center, it may be beneficial to maintain a purity of any fluids that contact or come into close proximity to computer equipment and/or one or more cold plate(s) associated therewith. Accordingly, certain embodiments of the present disclosure include a pump filtration system configured to filter a fluid, such as a working fluid (e.g., two-phase refrigerant), upstream of the computer equipment. For example, the fluid (e.g., working fluid, such as two-phase refrigerant) may be in a liquid form at the pump filtration system. The pump filtration system may include a spiral volute configured to bias the fluid in the liquid form into a cavity of the pump filtration system, a filter membrane disposed in or adjacent to the cavity, a motor, and an impeller. The impeller may be rotated by the motor to bias the fluid in the liquid form, for example, from the cavity and through the filter membrane, such that contaminants (e.g., particles of undesirably material constituents) are separated from the fluid in the liquid form by the filter membrane.

The fluid in the liquid (and now filtered) form may be output from the pump filtration system toward the computer enclosure(s). In certain embodiments, the fluid in the liquid (and now filtered) form extracts heat from the computer enclosure(s) and/or cold plate(s) associated therewith, which may cause the fluid to evaporate to a gas or vapor form. The fluid in the gas or vapor form may be received by a separator, a compressor, or both downstream from the computer enclosure(s) and/or cold plate(s) and passed to a condenser, which may operate to condense, cool, and/or subcool the fluid prior to delivery of the fluid in liquid form back to the pump filtration system. In general, the pump filtration system improves purity, movement, and/or delivery of a fluid (e.g., working fluid, refrigerant, two-phase refrigerant) in a data center cooling system, among other technical benefits, relative to traditional configurations. These and other aspects of the present disclosure are described in detail below with references to the drawings.

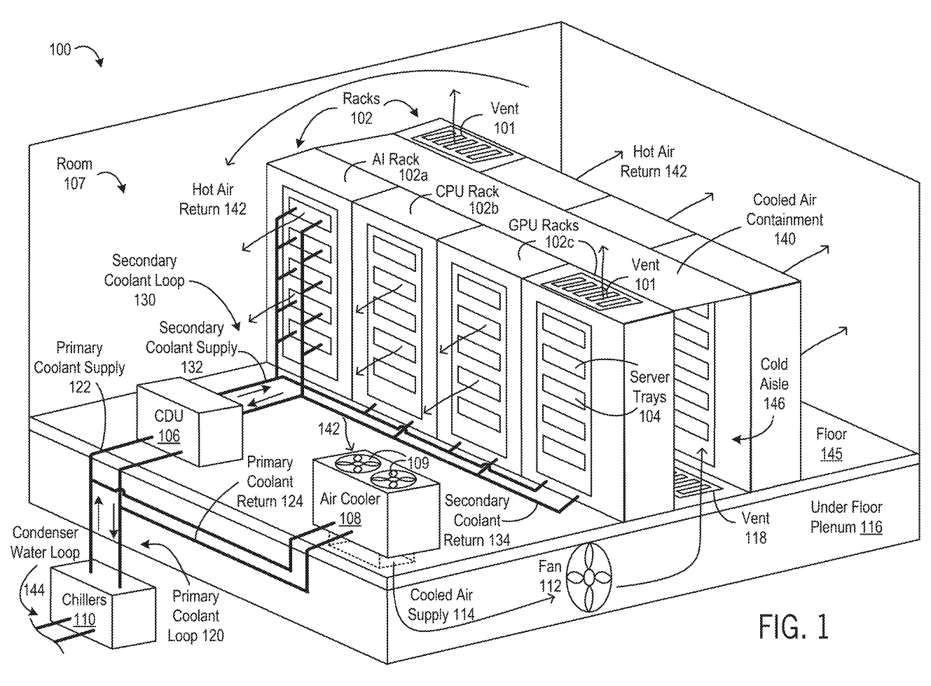

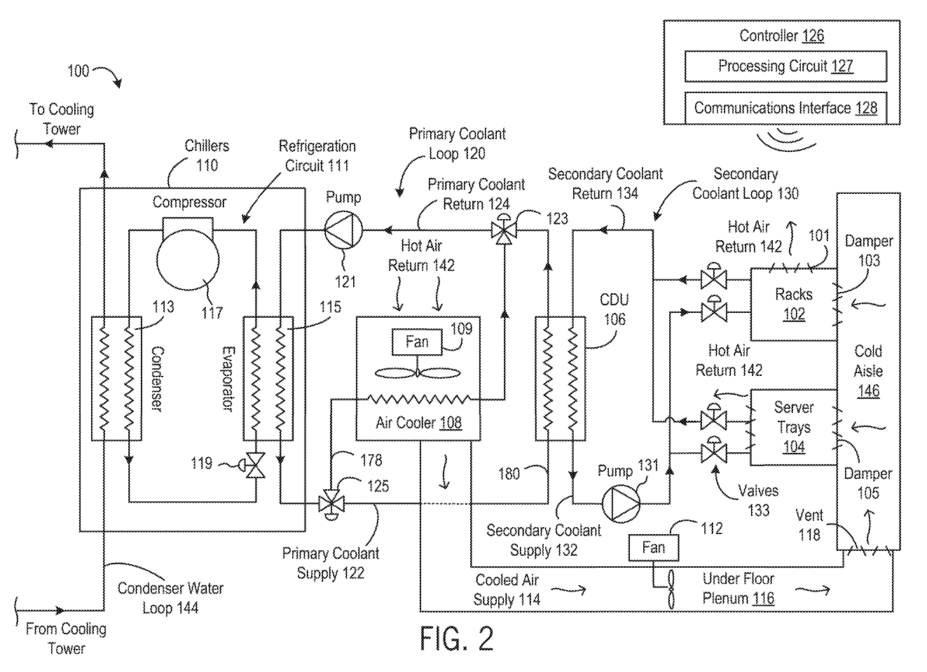

Referring now to FIGS. 1 and 2, a data center cooling system 100 is shown, according to an exemplary embodiment. FIG. 1 is a perspective view of a data center room 107 served by data center cooling system 100, whereas FIG. 2 is a block diagram of data center cooling system 100. Data center room 107 is shown to include several racks 102a, 102b, and 102c (collectively racks 102) containing server trays 104 (e.g., server blades, server boxes, other computing devices, etc.). Racks 102 may be arranged in rows (e.g., side-to-side) to form aisles between adjacent rows of racks 102. In some embodiments, the aisles form an alternating sequence of cold aisles and hot aisles on opposite sides of racks 102. For example, the space between the two rows of racks 102 in FIG. 1 is shown as a cold aisle 146 which provides a cooled air supply 114 to racks 102. Cold aisle 146 may be bounded on opposite sides by racks 102, on the bottom by floor 145 (i.e., the floor of data center room 107), and on the top by a cooled air containment 140 (e.g., a solid surface) to contain cooled air supply 114 within cold aisle 146. In some embodiments, cooled air containment 140 also extends vertically along the ends of cold aisle 146 to form a wall perpendicular to both the top surface of cooled air containment 140 and the front and rear surfaces of racks 102 (i.e., the surfaces on which server trays 104 are visible) to prevent cooled air supply 114 from escaping cold aisle 146 via the ends.

In some embodiments, the adjacent rows of racks 102 are arranged front-to-front (i.e., such that the front surfaces of adjacent rows of racks 102 face each other) and back-to-back (i.e., such that the rear surfaces of adjacent rows of racks 102 face each other). For example, as shown in FIG. 1, cold aisle 146 is located between the rear surfaces of adjacent rows of racks 102, whereas the front surfaces of racks 102 face toward hot aisles. In some embodiments, a vent 118 is located along floor 145 of cold aisle 146 to allow cooled air supply 114 to flow into cold aisle 146 from an under floor plenum 116. Racks 102 may draw or receive cooled air supply 114 into racks 102 from cold aisle 146 and pass cooled air supply 114 over heat-producing data center equipment contained within racks 102 (e.g., CPUs, GPUs, dual inline memory modules (DIMMs), servers, power supplies, etc.) which transfer heat to cooled air supply 114. The heated airflow then exits racks 102 through the front surfaces of racks 102 (i.e., the surfaces opposite cold aisle 146) and/or through the top surfaces of racks 102 via vents 101. The heated airflow exiting racks 102 then flows into data center room 107 as a hot air return 142.

In some embodiments, racks 102 can be designated as a particular type based on the type of computing devices they contain (e.g., CPUs, GPUs, DIMMs, ASICs, etc.) and/or based on the type of computing application they run during operation (e.g. AI applications, high performance computing applications, standard computing applications, etc.). For example, rack 102a is shown as an AI rack, rack 102b is shown as a CPU rack, and racks 102c are shown as GPU racks. Similarly, server trays 104 can be designated as AI server trays, CPU server trays, or GPU server trays based on the type of computing devices within server trays 104 and/or the type of computing applications by server trays 104. In some embodiments, data center cooling system 100 uses the type of racks 102 and/or server trays 104 to determine the amount of cooling to provide to each of racks 102 and/or server trays 104. For example, AI rack 102a and GPU racks 102c may require a higher amount of cooling whereas CPU rack 102b may require a lower amount of cooling. Similarly, AI server trays and GPU server trays may require a higher amount of cooling whereas CPU server trays may require a lower amount of cooling.

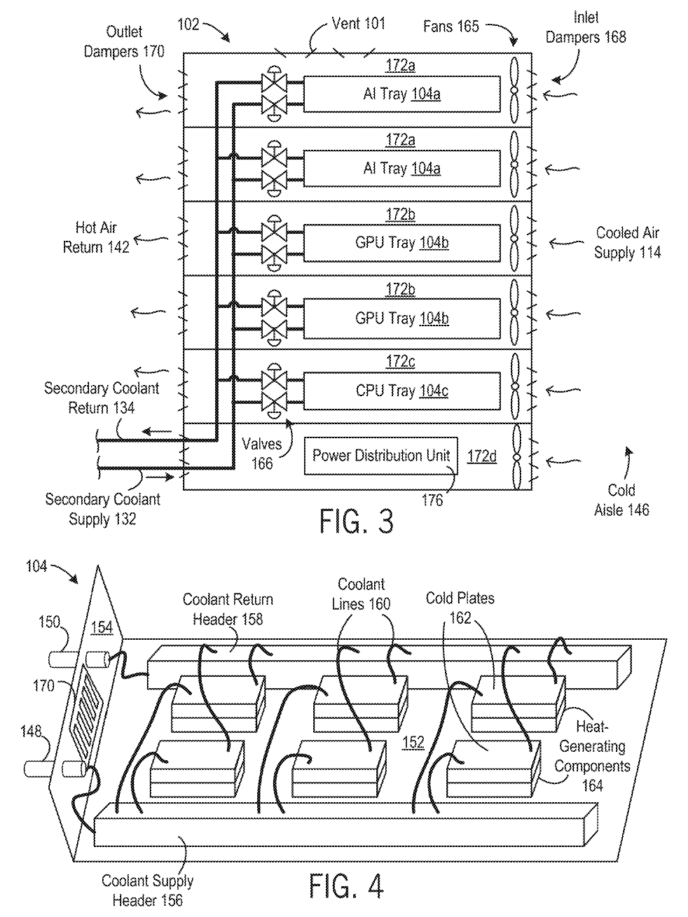

In various embodiments, racks 102 may include top vents 101 located on the top surfaces of racks 102, front vents aligned with each of server trays 104 on the front surfaces of racks 102, or a combination of top vents 101 and front vents. In some embodiments, one or more of racks 102 includes a top vent 101, whereas one or more other racks 102 include front vents. In racks 102 with top vents 101, some or all of the internal volume within such racks 102 may by fluidly connected to allow some or all of the airflow through such racks 102 to exit racks 102 via top vents 101. In racks 102 with front vents aligned with server trays 104, some or all of the internal volume within racks 102 may be portioned into separate compartments within which one or more of server trays 104 are contained. Each compartment may receive a separate airflow stream to provide targeted cooling to the heat-generating equipment contained within the corresponding compartment. One example of how racks 102 can be partitioned into isolated compartments is described in greater detail with reference to FIG. 3. Although only one of GPU racks 102c is shown with top vents 101 in FIG. 1, it is contemplated that any number or type of racks 102 can include top vents 101 and/or or front vents regardless of the type of rack 102. For example, any of AI rack 102a, CPU rack 102b, and/or GPU racks 102c can include front vents and/or top vents 101 in various embodiments.

Still referring to FIGS. 1 and 2, data center cooling system 100 is shown to include air cooling equipment (shown in subsequent figures as air cooling system 230) which provides air cooling to racks 102. The air cooling equipment are shown to include an air cooler 108 and fans 109 and 112 which operate to circulate airflow between air cooler 108 and racks 102. Fan 109 may be positioned to move hot air return 142 from data center room 107 into and through air cooler 108. Air cooler 108 may include any of a variety of airside HVAC equipment configured to provide cooling to hot air return 142 and/or generate cooled air supply 114. For example, air cooler 108 may include one or more computer room air conditioner (CRAC) units, computer room air handler (CRAH) units, direct evaporative cooling (DEC) units, indirect evaporative cooling (IEC) units, free cooling units (e.g., airside economizers), or any other type of airside HVAC equipment. Air cooler 108 may include one or more heat exchangers configured to absorb heat from hot air return 142 to generate cooled air supply 114. In various embodiments, air cooler 108 can be configured to provide mechanical cooling, free cooling, or a combination of mechanical cooling and free cooling to generate cooled air supply 114. For example, air cooler 108 can include any combination of mechanical cooling and free cooling components, as described U.S. Patent No. 9,982,903 granted May 29, 2018, the entire disclosure of which is incorporated by reference herein. Fan 109 can be operated to adjust the airflow rate of cooled air supply 114 and/or the amount of cooling provided to hot air return 142 to generate cooled air supply 114 by controlling the rate at which the airflow passes through air cooler 108.

In some embodiments, air cooler 108 generates cooled air supply 114 by removing heat from hot air return 142. For example, as shown in FIG. 2, air cooler 108 may include an internal heat exchanger (e.g., an air-to-liquid heat exchanger, a cooling coil, etc.) configured to transfer heat from the airflow passing through air cooler 108 into a primary coolant circulating through air cooler 108 via the heat exchanger. In some embodiments, air cooler 108 is configured to generate cooled air supply 114 by exhausting hot air return 142 (e.g., outdoors or into another space other than data center room 107) and drawing cool air into air cooler 108 (e.g., from outdoors or another space) to replace the exhausted hot air return 142. For example, air cooler 108 may operate as an airside economizer configured to provide free cooling to data center room 107 and/or racks 102 when outdoor temperature conditions permit the use of outdoor air. In various embodiments, air cooler 108 may generate cooled air supply 114 by mechanical cooling (e.g., removing heat from hot air return 142), by free cooling (e.g., replacing some or all of hot air return 142 with cooler outdoor air), or by using a combination of mechanical cooling and free cooling.

Air cooler 108 may deliver cooled air supply 114 into under floor plenum 116 which occupies a space below floor 145 of data center room 107. Fan 112 may be located within under floor plenum 116 and configured to move cooled air supply 114 through under floor plenum 116 and into cold aisle 146 via vent 118. Fan 112 can be operated to control the flow rate of cooled air supply 114 through under floor plenum 116 and into cold aisle 146. In some embodiments, data center cooling system 100 may include dampers 103 positioned at the air inlets of racks 102 (e.g., between racks 102 and cold aisle 146 as shown in FIG. 2). Dampers 103 can be operated to modulate the amount of airflow into each of racks 102 individually. Similarly, data center cooling system 100 may include dampers 105 positioned at the air inlets of server trays 104 (e.g., between server trays 104 and cold aisle 146 as shown in FIG. 2). In some embodiments, dampers 103 are used for racks 102 in which some or all of the internal volume is fluidly connected such that the amount of airflow into each rack 102 is controllable at the rack level. Conversely, dampers 105 may be used for racks 102 which are subdivided into compartments to control the airflow through each compartment individually. Although dampers 103 and 105 are shown at the inlets of racks 102 and server trays 104 respectively in FIG. 2, it is contemplated that dampers 103 and dampers 105 may be located at the outlets of racks 102 and server trays 104 or otherwise positioned within racks 102 to control the amount of airflow through each of racks 102 and/or compartments of racks 102.

Still referring to FIGS. 1 and 2, data center cooling system 100 is shown to include liquid cooling equipment (shown in subsequent figures as liquid cooling system 220) which provides liquid cooling to racks 102. The liquid cooling equipment are shown to include a coolant distribution unit (CDU) 106, chillers 110, a primary coolant loop 120, a secondary coolant loop 130, and a condenser water loop 144. Chillers 110 may be configured to provide cooling to a primary coolant (e.g., water, glycol, CO2, ammonia, etc.) which circulates between chillers 110, air cooler 108, and CDU 106 via primary coolant loop 120. As shown in FIG. 2, chillers 110 may include an internal refrigeration circuit 111 including a compressor 117, a condenser 113, an expansion valve 119, and an evaporator 115. Compressor 117 can be configured to circulate a refrigerant between condenser 113 and evaporator 115 via refrigeration circuit 111. Compressor 117 operates to compress the refrigerant to a high pressure, high temperature state. The compressed refrigerant flows through condenser 113, which transfers heat from the refrigerant in refrigeration circuit 111 to the water in condenser water loop 144. The cooled refrigerant then flows through expansion valve 119, which expands the refrigerant to a low temperature, low pressure state. The expanded refrigerant flows through evaporator 115, which transfers heat from the primary coolant in primary coolant loop 120 to the refrigerant in refrigeration circuit 111. In some embodiments, condenser water loop 144 circulates water or another coolant between condenser 113 and a cooling tower or other location (e.g., another heat exchanger) where the water rejects heat before returning to condenser 113.

In various embodiments, primary coolant loop 120 circulates the primary coolant between chillers 110 and one or both of CDU 106 and air cooler 108. Primary coolant loop 120 may include a pump 121 configured to circulate the primary coolant within primary coolant loop 120. Pump 121 can be operated to control the flow rate of the primary coolant within primary coolant loop 120. In some embodiments, primary coolant loop 120 includes one or more valves 123 and 125 configured to control the flow of the primary coolant through branches 178 and 180 of primary coolant loop 120. Branch 180 may pass through CDU 106, whereas branch 178 may pass through air cooler 108. In some embodiments, as shown in FIG. 2, valves 123 and 125 may be three-way valves positioned at the intersections of branches 178 and 180 (i.e., the location at which primary coolant loop 120 splits into branches 178 and 180) and can be operated to control the flow of the primary coolant supply 122 from chillers 110 to CDU 106 and/or to air cooler 108. Alternatively, valves 123 and 125 can be two-way valves having a single inlet and a single outlet (e.g., on/off valves, adjustable valves, modulating valves, etc.) located along each branch 178 and 180 of primary coolant loop 120 such that valves 123 and 125 can be operated to control the flow of the primary coolant to each of air cooler 108 and CDU 106 individually. In various embodiments, such two-way valves can be located between the intersections shown in FIG. 2 and air cooler 108 (e.g., upstream and/or downstream of air cooler 108), between the intersections shown in FIG. 2 and CDU 106 (e.g., upstream and/or downstream of CDU 106), or otherwise positioned along branches 178 and 180 to selectively control the flow rate of primary coolant supply 122 along each of branches 178 and 180.

The liquid coolant in primary coolant loop 120 is cooled by chillers 110 in evaporator 115 to generate primary coolant supply 122. Although only one evaporator 115 is shown in FIG. 2 for ease of illustration, it is contemplated that primary coolant loop 120 may include one or more evaporators 115 arranged in parallel (e.g., parts of parallel chillers 110) or in series (e.g., parts of series chillers 110) to provide cooling to the liquid coolant circulating in primary coolant loop 120. Primary coolant supply 122 flows through primary coolant loop 120 into branch 178 which passes through air cooler 108 and/or branch 180 which passes through CDU 106. The primary coolant absorbs heat from hot air return 142 in air cooler 108 and/or from the secondary coolant in CDU 106 to generate primary coolant return 124. Primary coolant return 124 then returns from air cooler 108 and/or CDU 106 to chillers 110 to be cooled once again and the cycle repeats.

In various embodiments, the liquid coolant circulating in primary coolant loop 120 can be cooled using any combination of mechanical cooling and/or free cooling. For example, in one embodiment a first portion (e.g., a first branch) of primary coolant loop 120 may pass through chillers 110 to receive mechanical cooling from chillers 110, whereas a second portion (e.g., a second branch) of primary coolant loop 120 may pass through one or more free cooling devices (e.g., outdoor air heat exchangers, cooling towers, etc.) to receive free cooling when outdoor temperature conditions permit using free cooling. Several examples of how a hybrid mechanical cooling and free cooling system can be constructed are described in detail in U.S. Patent No. 9,982,903 incorporated by reference above.

In some embodiments, data center cooling system 100 includes multiple primary coolant loops 120 configured to circulate the primary coolant at different temperatures. For example, a first primary coolant loop 120 may be configured to circulate a relatively higher temperature coolant, a second primary coolant loop 120 may be configured to circulate relatively colder temperature coolant, and a third primary coolant loop 120 may be configured to circulate coolant at a medium temperature between the relatively higher and lower temperatures. The

CDU 106 can be configured to transfer heat between the primary coolant in primary coolant loop 120 and the secondary coolant (e.g., water, glycol, CO2, ammonia, etc.) in secondary coolant loop 130. It is expected that the secondary coolant in secondary coolant loop 130 is warmer than the primary coolant in primary coolant loop 120 and thus the direction of heat transfer within CDU 106 is from the secondary coolant to the primary coolant (i.e., from secondary coolant loop 130 to primary coolant loop 120). In various embodiments, the primary coolant and the secondary coolant may be the same or different coolants and may be kept fluidly separate from each other by containing them within their respective coolant loops 120 and 130. CDU 106 is shown as a heat exchanger (e.g., a liquid-to-liquid heat exchanger, a heat exchange coil, etc.) which receives primary coolant supply 122 from primary coolant loop 120 and secondary coolant return 134 from secondary coolant loop 130. CDU 106 may transfer heat from the relatively warmer secondary coolant return 134 into the relatively colder primary coolant supply 122 to provide cooling to the secondary coolant and generate secondary coolant supply 132.

Secondary coolant loop 130 can be configured to circulate the secondary coolant between CDU 106 and one or both of racks 102 and server trays 104. Secondary coolant loop 130 may include a pump 131 configured to circulate the secondary coolant within secondary coolant loop 130. Pump 131 can be operated to control the flow rate of the secondary coolant within secondary coolant loop 130 and/or the rate of heat transfer between the primary coolant and the secondary coolant in CDU 106. In some embodiments, secondary coolant loop 130 includes one or more valves 133 configured to control the flow of the secondary coolant through racks 102 and/or server trays 104. In various embodiments, valves 133 may be located at the coolant inlets of racks 102 or server trays 104 and/or at the coolant outlets of racks 102 or server trays 104 to control the flow of the secondary coolant through each of racks 102 and/or server trays 104 individually. Although valves 133 are shown at both the inlets and outlets of racks 102 and server trays 104 in FIG. 2, it is contemplated that such an arrangement may be redundant and that a single valve located at either the inlet or the outlet of each of racks 102 or server trays 104 may be sufficient to control the flow of the secondary coolant through each of racks 102 and server trays 104 individually.

In some embodiments, secondary coolant loop 130 provides the secondary coolant to one or more of racks 102 in parallel. For example, as shown in FIG. 1, the three racks 102b and 102c are shown receiving secondary coolant supply 132 from secondary coolant loop 130 and discharging secondary coolant return 134 as an output of racks 102. Such racks 102b and 102c may have internal valves (e.g., valves 166 shown in FIG. 3), pumps, or other flow control devices which can be operated to independently control the flow of secondary coolant supply 132 to each of server trays 104 and/or individual heat-generating components 164 located within racks 102b and 102c, as described in greater detail with reference to FIGS. 3 and 4. In some embodiments, secondary coolant loop 130 provides the secondary coolant directly to one or more of server trays 104 in parallel. For example, as shown in FIG. 1, rack 102a is shown with secondary coolant supply 132 being delivered to each of server trays 104 of rack 102a in parallel. In various embodiments, secondary coolant loop 130 can deliver the secondary coolant to one or more of racks 102 and/or one or more of server trays 104 in parallel.

Although server trays 104 are shown separate from racks 102 in FIG. 2, it is understood that server trays 104 may be installed within racks 102 and thus may be considered components of racks 102 in some embodiments. The separate depiction of racks 102 and server trays 104 in FIG. 2 is intended to illustrate that the air cooling system (e.g., air cooler 108, fans 109 and 112, dampers 103 and 105, etc.) may provide cooled air supply 114 directly to one or more of server trays 104 (e.g., directly from cold aisle 146) without first requiring cooled air supply 114 to enter the racks 102 within which such server trays 104 are contained. For example, one or more of server trays 104 may have a cooled air intake located along an edge or surface of racks 102 adjacent to cold aisle 146 and configured to receive cooled air supply 114 directly from cold aisle 146 (e.g., via dampers 105). Accordingly, the amount of cooling provided to each of server trays 104 by the air cooling system can be independently adjusted by controlling the airflow rate of cooled supply air 114 and/or the temperature of cooled supply air 114 provided to each of server trays 104 individually. Other server trays 104 may be located within a shared volume within racks 102 and configured to receive cooled air supply 114 after cooled air supply 114 enters racks 102. For example, racks 102 may include dampers 103 which can be operated to control the flow rate of cooled air supply 114 into each of racks 102 individually. In racks 102 with a single large compartment containing multiple server trays 104, cooled air supply 114 may pass across or through multiple server trays 104 within a given rack 102 after entering the rack 102 (e.g., via dampers 103).

Although AI rack 102a is the only type of racks 102 shown in FIG. 1 as receiving the secondary coolant directly from secondary coolant loop 130 to each of server trays 104 within rack 102a, it is contemplated that any of racks 102 can be connected to secondary coolant loop 130 at the server tray level (i.e., with a separate coolant inlet and outlet for each of server trays 104 within the rack) and that such connectivity is not limited to racks 102 designated as AI racks. For example, any of CPU rack 102b and/or GPU racks 102c can also or alternatively be connected to secondary coolant loop 130 at the server tray level in various embodiments. Similarly, while CPU rack 102b and GPU racks 102c are the only type of racks 102 shown in FIG. 1 with a single coolant inlet and single coolant outlet connecting to secondary coolant loop 130, it is contemplated that any of racks 102 can be connected to secondary coolant loop 130 at the rack level (i.e., with a single coolant inlet and outlet for the rack as a whole) and that such connectivity is not limited to racks designated as CPU racks or GPU racks. For example, AI rack 102a can also or alternatively be connected to secondary coolant loop 130 at the rack level in some embodiments.

In some embodiments, primary coolant loop 120 and/or secondary coolant loop 130 supply a liquid coolant (e.g., water, glycol, etc.) to racks 102, server trays 104, and/or to individual heat-generating components installed on server trays 104 (e.g., CPUs, GPUs, etc.) to provide targeted cooling to such components. However, it is contemplated that data center cooling system 100 is not limited to using liquid coolants in primary coolant loop 120 and/or secondary coolant loop 130, but rather can use any of a variety of fluid coolants in various embodiments (e.g., gas coolants, liquid coolants, vapor coolants, mixed phase (liquid/vapor, liquid/gas) coolants, and/or any other type of fluid coolant). Accordingly, it should be understood that all references to liquid coolants throughout the present disclosure including the claims presented herein can be replaced with any other type of fluid coolant without departing from the teachings of the present disclosure.

Referring now to FIG. 3, one of racks 102 is shown in greater detail, according to an exemplary embodiment. Rack 102 is shown to include several compartments 172a, 172b, 172c, and 172d (collectively compartments 172) containing different types of server trays 104 and a power distribution unit (PDU) 176. In particular, compartments 172a are shown containing AI trays 104a, compartments 172b are shown containing GPU trays 104b, compartment 172c is shown containing CPU tray 104c, and compartment 172d is shown containing PDU 176. As noted above, the types of server trays 104 within compartments 172 may correspond to the types of computing applications run by server trays 104 and/or the types of computing devices located on server trays 104 (e.g., AI applications, high performance computing applications, GPUs, CPUs, DIMMS, etc.).

In some embodiments, compartments 172 are fluidly isolated from each other (e.g., by solid surfaces within racks 102 forming upper and lower boundaries of compartments 172) such that the airflow streams through compartments 172 do not mix with each other within racks 102. Accordingly, each of compartments 172 may receive a separate stream of cooled air supply 114 from cold aisle 146 for use in cooling the heat-producing data center equipment therein. The streams of cooled air supply 114 may be kept separate from each other within racks 102 such that each stream of cooled air supply 114 cools a corresponding compartment 172. In other embodiments, racks 102 may not include compartments 172 (or one or more of compartments 172 may be joined into a larger compartment) such that some or all of the internal volume within racks 102 is fluidly connected. In such an embodiment, racks 102 may receive one or more streams of cooled air supply 114 from cold aisle 146 and may allow the streams of cooled air supply 114 to mix or join within racks 102.

In some embodiments, racks 102 include inlet dampers 168 positioned at the cold air intake of racks 102 (e.g., between cold aisle 146 and compartments 172). Inlet dampers 168 may be aligned with compartments 172 and individually operated to independently control the flow of cooled air supply 114 into and through each of compartments 172. Dampers 103 and 105 shown in FIG. 2 may be types of inlet dampers 168 shown in FIG. 3. Similarly, racks 102 may include inlet dampers 168 positioned at the hot air exhaust of racks 102 (e.g., between compartments 172 and the hot aisle or data center room 107). Outlet dampers 170 may be aligned with compartments 172 and individually operated to independently control the flow of cooled air supply 114 out of and through each of compartments 172. Although compartments 172 are shown equipped with both inlet dampers 168 and outlet dampers 170 in FIG. 3, it is contemplated that such an arrangement may be redundant and that only one of inlet dampers 168 or outlet dampers 170 may be installed and used to control the airflow through each of compartments 172 in some embodiments. Alternatively, both inlet dampers 168 and outlet dampers 170 may be installed and used to control the airflow through compartments 172 in some embodiments.

In some embodiments, cooled air supply 114 within cold aisle 146 is maintained at an air pressure above the air pressure within data center room 107 such that the pressure differential causes cooled air supply 114 to flow through compartments 172 when inlet dampers 168 and/or outlet dampers 170 are open. For example, air cooler 108 and/or fan 112 may be operated to maintain cold aisle 146 at a positive air pressure relative to the air pressure within data center room 107. In some embodiments, racks 102 include fans 165 positioned within each compartment 172 (e.g., upstream or downstream of server trays 104). Fans 165 can be operated to independently control the flow rate of cooled air supply 114 through each of compartments 172 to provide different air flow rates to different server trays 104 within a given rack 102.

For racks 102 that contain multiple compartments 172, each compartment 172 may be equipped with an inlet damper 168, outlet damper 170, and/or fan 165. These components can be operated to independently control the flow rate of cooled air supply 114 through each compartment 172, and thus modulate the amount of cooling provided to each of server trays 104 by cooled air supply 114. For racks 102 that do not contain multiple compartments 172, such racks 102 may include one or more of inlet dampers 168, outlet dampers 170, and/or fans 165 which can be operated to control the flow rate of cooled air supply 114 through the rack 102 as a whole. In this way, each rack 102 can be provided with a different amount of air cooling either at the rack level or at the server tray level. In some embodiments, inlet dampers 168 and/or outlet dampers 170 can be replaced with vents or held permanently open to provide the same functionality as a vent. In such embodiments, airflow through each of compartments 172 can be controlled by operating fans 165 and/or by controlling the air pressure within cold aisle 146.

Still referring to FIG. 3, rack 102 is shown to include valves 166. Valves 166 may be located along secondary coolant loop 130 and operated to control the flow of the secondary coolant through rack 102 and/or server trays 104. In various embodiments, valves 166 can be located along secondary coolant supply 132 (e.g., upstream of server trays 104), along secondary coolant return 134 (e.g., downstream of server trays 104), or in both locations as shown in FIG. 3. However, it is contemplated that positioning valves 166 both upstream and downstream of server trays 104 may be redundant and that only one of an upstream valve 166 or a downstream valve 166 may be required to control the flow of the secondary coolant through rack 102 and/or server trays 104. In some embodiments, rack 102 includes one or more valves 166 within each of compartments 172 or otherwise positioned to control the flow of the secondary coolant to each of server trays 104 individually. Such an arrangement allows each of server trays 104 to receive a different flow rate of the secondary coolant from secondary coolant supply 132 (e.g., by operating valves 166) to modulate the amount of liquid cooling provided to each of server trays 104 independently. Although not explicitly shown in FIG. 3, it is contemplated that PDU 176 may also be cooled by secondary coolant loop 130 and may receive a flow of secondary coolant supply 132 in some embodiments.

In some embodiments, valves 166 and/or valves 133 can be operated to open or close different branches of secondary coolant loop 130. For example, valves 133 shown in FIG. 2 can be closed to prevent the secondary coolant from flowing into and through one or more of racks 102 or server trays 104 connected in series with valves 133, or opened to allow the secondary coolant to flow through into and through one or more of racks 102 or server trays 104 connected in series with valves 133. Similarly, valves 166 shown in FIG. 3 can be opened or closed to allow the secondary coolant to flow through individual server trays 104 within a given rack 102 while preventing the secondary coolant from flowing through other server trays 104 within a given rack 102. Valves 166 and 133 can be modulated between fully open positions and fully closed positions (i.e., set to any position between and including fully open and fully closed) to selectively control the amount of proportion of the secondary coolant that flows through each of racks 102 and/or server trays 104. In this way, the flow of the secondary coolant can be controlled (e.g., increased, decreased, etc.) or cut-off entirely to some or all of racks 102 or server trays 104 based on their individual cooling requirements. In some embodiments, valves 166 and 133 can be closed to allow some racks 102 or server trays 104 to be disconnected from secondary coolant loop 130 (e.g., for maintenance, replacement, etc.). Valves 166 and 133 can also or alternatively be closed to increase the efficiency of pump 131 by preventing pressure losses within secondary coolant loop 130 caused by pumping the secondary coolant through racks 102 or server trays 104 that do not require liquid cooling.

Referring now to FIG. 4, one of server trays 104 is shown in greater detail, according to an exemplary embodiment. Server tray 104 is shown to include a surface 152 (e.g., a bottom surface, a board, a substrate, etc.) on which one or more heat-generating components 164 are mounted or installed. Heat-generating components 164 may include any type of computing device or other data center component that generates heat during operation (e.g., CPUs, GPUs, ASICs, DIMMs, power supplies, etc.). Server tray 104 is shown to include cold plates 162 thermally coupled to heat-generating components 164 (e.g., positioned on or near heat-generating components 164 to facilitate heat transfer between cold plates 162 and heat-generating components 164) and configured to absorb heat from heat-generating components 164 during operation. Cold plates 162 may include heat sinks, tubes, liquid-to-solid heat exchangers, or any other structure configured to draw heat away from heat-generating components 164. Cold plates 162 may receive flows of the secondary coolant from secondary coolant loop 130 and transfer heat from heat-generating components 164 into the secondary coolant.

Server tray 104 is shown to include a front surface 154 having a coolant inlet port 148 and a coolant outlet port 150. Coolant inlet port 148 may be connected to secondary coolant supply 132 and may receive a flow of the chilled secondary coolant from secondary coolant loop 130. The chilled secondary coolant may flow from coolant inlet port 148 into a coolant supply header 156. Coolant supply header 156 may be connected to each of cold plates 162 via coolant lines 160 and may deliver the chilled secondary coolant to cold plates 162. The secondary coolant absorbs heat from cold plates 162 and thus provides cooling to heat-generating components 164 thermally coupled to cold plates 162. The warmed secondary coolant then flows from cold plates 162 into coolant return header 158 via coolant lines 160. Coolant return header 158 may be fluidly coupled with coolant outlet port 150 and configured to discharge the warmed secondary coolant back to secondary coolant loop 130 via coolant outlet port 150.

In some embodiments, cold plates 162 also or alternatively include fins, plates, solid-to-air heat exchangers, or other structures configured to transfer heat from cold plates 162 into cooled air supply 114 flowing across server tray 104. Cooled air supply 114 may flow across server tray 104 and absorb heat from heat-generating components 164 either directly or via cold plates 162. The warmed airflow may then exit server tray 104 via front surface 154 through outlet damper 170 and/or a front vent in various embodiments.

Referring generally to FIGS. 1-4, data center cooling system 100 may include a variety of sensors (e.g., temperature sensors, flow rate sensors, pressure sensors, etc.) positioned to measure the temperatures, flow rates, pressures, or other conditions of the airflow and liquid coolant at various locations within data center cooling system 100. For example, data center cooling system 100 may include air sensors positioned at the inlet or outlet of air cooler 108 (e.g., upstream or downstream of the heat exchanger within air cooler 108), within under-floor plenum 166, at the air inlet or outlet of each rack 102 (e.g., upstream or downstream of server trays 104), at the air inlet or outlet of each of compartments 172 (e.g., proximate to inlet dampers 168 or outlet dampers 170), within compartments 172, within data center room 107, or otherwise within the data center to measure the temperatures, flow rates, pressures, and/or other conditions of the airflow at the locations of the air sensors. For example, data center cooling system 100 may include flow rate sensors and/or temperature sensors configured to measure the flow rate or temperature of cooled air supply 114 entering each of racks 102 or each of compartments 172 and/or the flow rate or temperature of hot air return 142 exiting each of racks 102 or each of compartments 172 independently.

Data center cooling system 100 may include liquid coolant or refrigerant sensors positioned at the coolant inlets or outlets of chillers 110 (e.g., along primary coolant loop 120 upstream or downstream of evaporator 115), at any location within refrigeration circuit 111, at the coolant inlets or outlets of CDU 106 (e.g., along primary coolant loop 120 upstream or downstream of CDU 106, along secondary coolant loop 130 upstream or downstream of CDU 106), at the inlets or outlets of individual racks 102 or server trays 104 (e.g., along secondary coolant supply 132 or secondary coolant return 134), or immediately upstream or downstream of individual heat-generating components 164 within server trays 104 to measure the temperatures, flow rates, pressures, and/or other conditions of the liquid coolant or refrigerant at the locations of the liquid coolant or refrigerant sensors. For example, data center cooling system 100 may include flow rate, pressure, or temperature sensors configured to measure the flow rate, pressure, or temperature of the primary coolant entering or exiting chillers 110 (e.g., position upstream or downstream of chillers 110 along primary coolant loop 120), the secondary coolant entering or exiting CDU 106 (e.g., along secondary coolant loop 130 upstream or downstream of CDU 106), the secondary coolant entering or exiting racks 102 or server trays 104 (e.g., along secondary coolant loop 130 upstream or downstream or racks 102 or server trays 104), the refrigerant in refrigeration circuit 111 (e.g., between any of condenser 113, expansion valve 119, evaporator 115, and compressor 117), along condenser water loop 144 upstream or downstream of chillers 110, or otherwise positioned to measure any variable state or condition of the refrigerant, primary coolant, secondary coolant, or condenser water any ant location in data center cooling system 100.

In some embodiments, data center cooling system 100 includes temperature sensors configured to measure the temperatures of heat-generating components 164 (e.g., CPU temperatures, GPU temperatures, etc.). Such temperature sensors may be integrated with heat-generating components 164 (e.g., internal thermocouples or other built-in temperature sensors) or additional components of data center cooling system 100 installed to measure the temperatures at or near each of heat-generating components 164. In some embodiments, data center cooling system 100 includes power sensors configured to measure the amount of power delivered to each of racks 102, server trays 104, heat-generating components 164, or other computing devices within the data center. In some embodiments, the power sensors are implemented as wattage sensors, current sensors, or voltage sensors configured to measure the amount of electric power delivered to various components of the data center or measure variables from which power can be derived (e.g., voltage, current, etc.).

Referring particularly to FIG. 2, data center cooling system 100 is shown to include a controller 126. Controller 126 is shown to include a processing circuit 127 and a communications interface 128. Processing circuit 127 may include one or more processors and memory. The processors (shown in subsequent figures as processor 222) may include one or more general purpose or specific purpose processors, application specific integrated circuits (ASIC), one or more field programmable gate arrays (FPGAs), a group of processing components, or other suitable processing components. The processors may be configured to execute computer code or instructions stored in the memory or received from other computer readable media (e.g., CDROM, network storage, a remote server, etc.). The memory (shown in subsequent figures as memory 223) may include one or more devices (e.g., memory units, memory devices, storage devices, etc.) for storing data and/or computer code for completing and/or facilitating the various processes described in the present disclosure. The memory may include random access memory (RAM), read-only memory (ROM), hard drive storage, temporary storage, non-volatile memory, flash memory, optical memory, or any other suitable memory for storing software objects and/or computer instructions. The memory may include database components, object code components, script components, or any other type of information structure for supporting the various activities and information structures described in the present disclosure. The memory may be communicably connected to the processors via processing circuit 127 and may include computer code for executing (e.g., by the processors) one or more processes described herein.

Communications interface 128 may include wired or wireless interfaces (e.g., jacks, antennas, transmitters, receivers, transceivers, wire terminals, etc.) for conducting data communications with various systems, devices, or networks. For example, communications interface 128 may include an Ethernet card and port for sending and receiving data via an Ethernet-based communications network and/or a Wi-Fi transceiver for communicating via a wireless communications network. Communications interface 128 may be configured to communicate via local area networks or wide area networks (e.g., the Internet, a building WAN, etc.) and may use a variety of communications protocols (e.g., BACnet, IP, LON, etc.). Communications interface 128 may be configured to facilitate electronic data communications between controller 126 and various other systems or devices of data center cooling system 100 (e.g., sensors, controllable equipment, etc.) or other external data sources, systems, or devices outside data center cooling system 100. For example, controller 126 may be configured to communicate with any or all of the controllable equipment of data center cooling system 100 (e.g., CDU 106, air cooler 108, fan 109, chillers 110, fan 112, compressor 117, expansion valve 119, pump 121, valve 123, valve 125, valves 133, pump 131, dampers 103, dampers 105, inlet dampers 168, outlet dampers 170, valves 166, fans 165, etc.) and any or all of the sensors in data center cooling system 100 (e.g., any of the temperature sensors, pressure sensors, flow rate sensors, power sensors, etc.).

Controller 126 can be configured to receive measurements from the sensors and operate the controllable equipment of data center cooling system 100 to control the flow rates, pressures, temperatures, or other variable states or conditions of cooled air supply 114, hot air return 142, the refrigerant in refrigeration circuit 111, the condenser water in condenser water loop 144, the primary coolant in primary coolant loop 120, the secondary coolant in secondary coolant loop 130, or any portions thereof. In some embodiments, controller 126 receives reported values of temperatures, power consumption, or other measured or calculated variables from heat-generating components 164, PDU 176, or other data center equipment configured to report their own operating conditions (e.g., temperatures, power consumption, power delivered, computing load, etc.).

Controller 126 can use any of a variety of feedback control processes (e.g., closed-loop control, reset control, etc.), feedforward or predictive control processes (e.g., model predictive control, prediction-based control, etc.), or other control processes to operate the controllable equipment of data center cooling system 100 based on the measured values from installed sensors or reported variables from the data center equipment. Several examples of particular control processes which can be performed by controller 126 are described in detail below. Advantageously, controller 126 can be configured to precisely modulate the amount of cooling provided to each of racks 102, server trays 104, and/or individual heat-generating components 164 (referred to generally as “heat loads”) by both the air cooling equipment and the liquid cooling equipment of data center cooling system 100. Controller 126 can independently adjust the amount of cooling provided individual heat loads within the data center by controlling the air cooling equipment and the liquid cooling equipment that serve each heat load independently. This allows controller 126 to provide targeted cooling to various heat loads as needed without overcooling other heat loads more than necessary to dissipate the amount of heat generated during operation.

In some embodiments, data center cooling system 100 includes some or all of the components, features, or functionality described in U.S. Patent Application No. 17/741,108 filed May 10, 2022, U.S. Patent No. 11,497,144 granted Nov. 8, 2022, U.S. Patent Application No. 18/308,418 filed Apr.27, 2023, U.S. Patent Application No. 18/308,422 filed Apr. 27, 2023, U.S. Patent Application No. 18/641,658 filed Apr. 22, 2024, Indian Provisional Patent Application No. 202441090506 filed Nov. 2021, 2024, U.S. Provisional Patent Application No. 63/804,615 filed May 12, 2025, U.S. Provisional Patent Application No. 63/804,544 filed May 12, 2025, U.S. Provisional Patent Application No. 63/804,546 filed May 12, 2025, U.S. Provisional Patent Application No. 63/804,553 filed May 12, 2025, and/or U.S. Provisional Patent Application No. 63/804,558 filed May 12, 2025, all of which are incorporated by reference herein in their entireties. For example, controller 126 can be configured to execute any or all of the control processes described in any of the patents, patent applications, or other documents incorporated by reference throughout the present disclosure in the context of data center cooling system 100. Data center cooling system 100 can include any or all of the equipment described in any of the aforementioned documents in various embodiments. In addition to the functionality described in these documents, controller 126 can be configured to execute a variety of new control processes that improve upon the prior art in various ways, several examples of which are described in detail below.

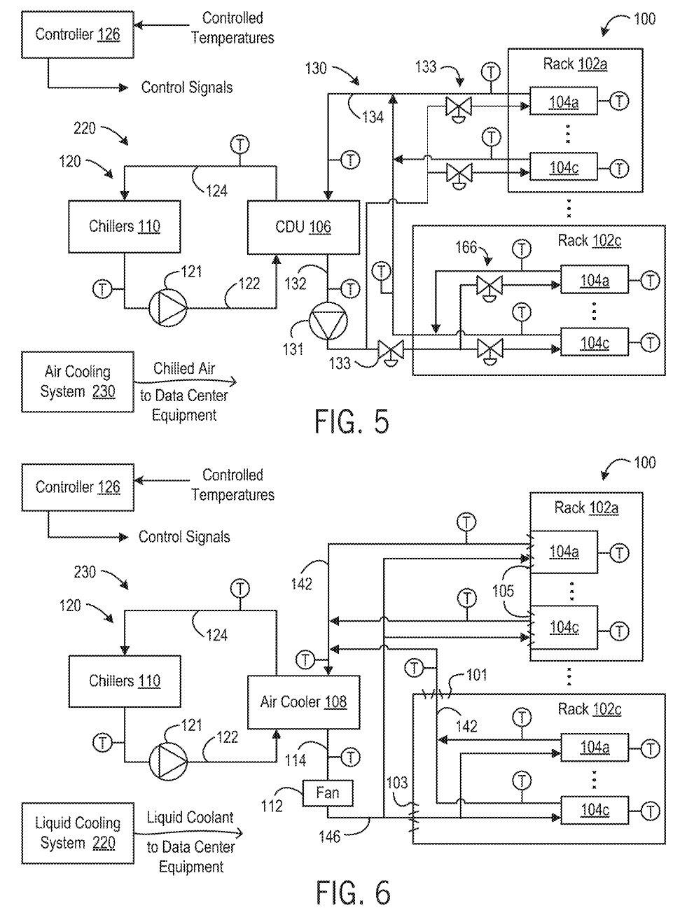

Referring now to FIGS. 5 and 6, data center cooling system 100 is shown in greater detail, according to some embodiments. FIG. 5 illustrates the fluid connections of liquid cooling system 220 including primary coolant loop 120 and secondary coolant loop 130 (referred to herein as liquid cooling loops or liquid cooling circuits). Primary coolant loop 120 circulates a primary coolant between chillers 110 and CDU 106. The primary coolant exits chillers 110 into primary coolant supply 122 and then flows into CDU 106 wherein the primary coolant absorbs heat from the secondary coolant. The primary coolant then exits CDU 106 and flows into primary coolant return 124 after absorbing heat from the secondary coolant in CDU 106. Pump 121 operates to circulate the primary coolant between chillers 110 and CDU 106 and can be located along primary coolant supply 122 and/or primary coolant return 124 in various embodiments. Temperature sensors (shown as circles containing “T” in FIGS. 5 and 6) can be located along primary coolant supply 122 and configured to measure the temperature of the primary coolant exiting chillers 110 or entering CDU 106. Temperature sensors can also or alternatively be located along primary coolant return 124 and configured to measure the temperature of the primary coolant exiting CDU 106 or entering chillers 110.

Secondary coolant loop 130 circulates a secondary coolant between CDU 106, racks 102, and/or server trays 104. The secondary coolant exits CDU 106 after rejecting heat to the primary coolant and flows into secondary coolant supply 132. Valves 133 may be located along secondary coolant supply 132 and can be operated to control the flow of the secondary coolant into each of racks 102 individually. In some embodiments, one or more of racks 102 includes additional valves 166 which can be operated to control the flow of the secondary coolant in to each of server trays 104 individually. Pump 131 operates to circulate the secondary coolant between CDU 106, racks 102, and/or server trays 104 and can be located along secondary coolant supply 132 and/or secondary coolant return 134 in various embodiments. In some embodiments, controller 126 operates CDU 106 to maintain the temperature of the liquid coolant in secondary coolant supply 132 and/or secondary coolant return 134 at or above a dew point temperature of the air within the data center to prevent condensation on liquid lines.

Temperature sensors can be located along any of secondary coolant supply 132 (e.g., at the outlet of CDU 106, at the inlets of racks 102, at the inlets of server trays 104, etc.), secondary coolant return 134 (e.g., at the inlet of CDU 106, at the outlets of racks 102 and/or server trays 104, etc.) and configured to measure the temperature of the secondary coolant at the locations of the temperature sensors. In some embodiments, secondary coolant loop 130 includes a temperature sensor located at the outlet of each of racks 102 and/or server trays 104 and configured to measure the temperatures of the secondary coolant exiting each of racks 102 and/or server trays 104. In some embodiments, data center cooling system 100 includes temperature sensors configured to measure the temperatures of each of racks 102, server trays 104, and/or individual components of data center equipment 240 (e.g., CPU temperatures, GPU temperatures, etc.).

FIG. 6 illustrates the fluid connections of air cooling system 230 including primary coolant loop 120 and an air cooling loop 232. Primary coolant loop 120 may be the same as described with reference to FIG. 5 with the exception that primary coolant loop 120 delivers the primary coolant to air cooler 108. Air cooler 108 transfers heat from the air into the primary coolant to generate cooled air supply 114. Temperature sensors can be located along primary coolant supply 122 and configured to measure the temperature of the primary coolant exiting chillers 110 or entering air cooler 108. Temperature sensors can also or alternatively be located along primary coolant return 124 and configured to measure the temperature of the primary coolant exiting air cooler 108 or entering chillers 110.

Air cooling loop 232 (e.g., an air cooling circuit) circulates air between air cooler 108, racks 102, and/or server trays 104. Cooled air supply 114 exits air cooler 108 and is circulated by fan 112 through cold aisle 146 and into racks 102 via dampers 103 and/or into server trays 104 via dampers 105. Cooled air supply 114 absorbs heat from data center equipment 240within racks 102 and/or server trays 104 and exits racks 102 and/or server trays 104 via top vents 101 and/or dampers 105. Temperature sensors can be positioned to measure the temperature of the cooled air supply 114 exiting air cooler 108 (e.g., within cold aisle 146, at the inlets of racks 102 and/or server trays 104, etc.), the temperature of the air exiting racks 102 and/or server trays 104 (e.g., immediately downstream of racks 102 and/or server trays 104, at the outlets of racks 102 and/or server trays 104), or any other location within air cooling loop 232. In general, temperature sensors can be located at any of the positions shown in FIGS. 5 and 6 or otherwise located in liquid cooling system 220 and/or air cooling system 230 to measure the temperatures of the primary coolant, secondary coolant, cooled air, or other coolant temperatures at any location within liquid cooling system 220 and/or air cooling system 230.

Some cooling systems implemented with data centers include numerous stages of heat exchange, which may limit an overall efficiency or effectiveness of such cooling systems to transfer and reject heat generated by electronic equipment in data centers. To this end, present embodiments are directed to improved configurations of cooling systems configured to provide cooling to electronic equipment with increased efficiency and effectiveness. For example, certain cooling systems incorporating the techniques described herein include a chiller system and/or a condensing unit having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment.

In other embodiments, the chiller system and/or condensing unit may be configured to cool the working fluid and direct the working fluid to the electronic equipment to place the working fluid in a heat exchange relationship with the electronic equipment, such as via a chilled plate, a tube, a flow path, a channel, a vessel, and/or immersion cooling techniques. In such embodiments, the cooling system may or may not include a conditioning fluid circuit configured to place a conditioning fluid in a heat exchange relationship with the electronic equipment. Accordingly, certain embodiments discussed herein may not incorporate a CDU that includes a heat exchanger configured to enable heat transfer between two flows of fluid, such as the conditioning fluid cooled by a chiller system and a coolant placed in a heat exchange relationship with electronic equipment. Therefore, a stage of heat transfer typically included in some cooling systems is omitted in certain embodiments of the present disclosure, which enables enhanced efficiency of the chiller system and increased heat rejection of heat generated by the electronic equipment.

Present embodiments also include a chiller system having an evaporator configured to cool a conditioning fluid that is suitable for placing in a heat transfer arrangement with electronic equipment. For example, the evaporator may include one or more components that form a portion of a conditioning fluid circuit extending from the evaporator to the electronic equipment, whereby the components are configured to enable generation of the conditioning fluid while mitigating exposure of the conditioning fluid to potential particulates or contaminants within the evaporator. The evaporator may include tubes configured to circulate the conditioning fluid through the evaporator and one or more water boxes (e.g., manifolds) configured to receive the flow of conditioning fluid from piping of the conditioning fluid circuit and/or discharge the flow of conditioning fluid to the piping. The tubes and the water boxes may each be formed from a respective material (e.g., non-corrosive material, degradation resistant material, copper, stainless steel, etc.) suitable for exposure to the conditioning fluid that is placed in a heat exchange relationship with the electronic components. The evaporator also may include a cladding assembly configured to maintain fluid separation between the two fluids received by the evaporator.

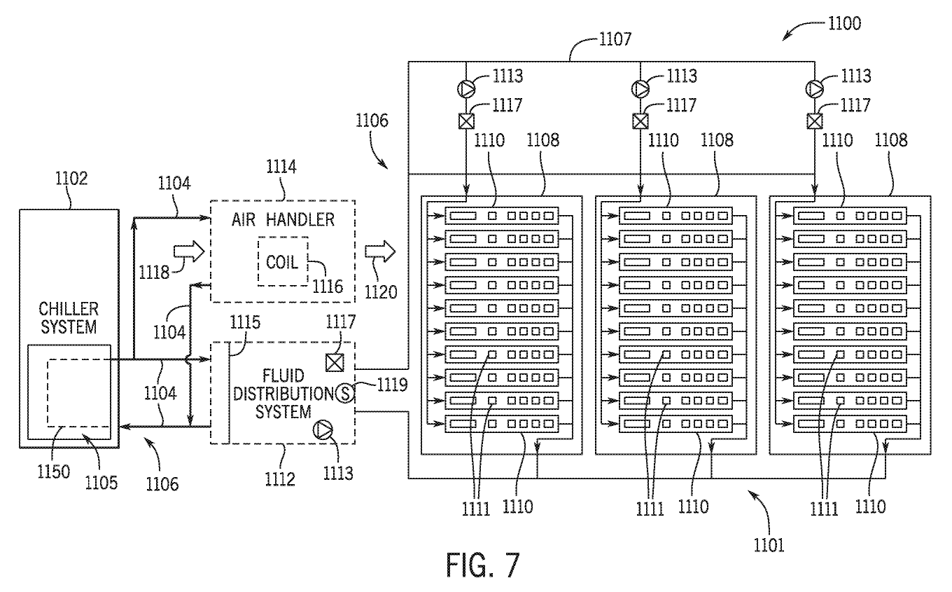

With the preceding in mind, FIG. 7 is a schematic of an embodiment of a cooling system 1100 (e.g., computer cooling system, electronic equipment cooling system, data center cooling system) configured to provide cooling to electronic equipment 1101. The cooling system 1100 includes a chiller system 1102 (e.g., vapor compression system 30) configured to generate a conditioning fluid 1104 (e.g., working fluid, conditioning fluid, two-phase fluid, single-phase fluid) that is directed to the electronic equipment 1101 via a conditioning fluid circuit 1106 (e.g., conditioning fluid loop) to absorb heat generated by the electronic equipment 1101. The conditioning fluid circuit 1106 may also direct the conditioning fluid 1104 from the electronic equipment 1101 back to the chiller system 1102 to enable rejection of heat absorbed by the conditioning fluid 1104 from the electronic equipment 1101. In some embodiments, the chiller system 1102 may be an air-cooled chiller. For example, the chiller system 1102 may include a working fluid circuit having a compressor system, one or more condensers (e.g., condenser coils, heat exchangers), and one or more evaporators (e.g., shell and tube evaporators), such as an evaporator 1150. In an embodiment of the chiller system 1102 configured as an air-cooled chiller, the compressor system may circulate a working fluid along the working fluid circuit, the condensers may enable transfer of heat from the working fluid to ambient air, and the evaporator 1150 may enable transfer of heat from the conditioning fluid 1104 (e.g., water) to the working fluid. However, it should be appreciated that the chiller system 1102 may include other configurations and/or components, such as a water-cooled chiller, a cooling tower, a dry cooler, another suitable components or system, or any combination thereof. In some embodiments, the cooling system 1100 may include an air handler 1114 (e.g., air handling unit) having a heat exchanger 1116 (e.g., coil) configured to receive the conditioning fluid 1104 and/or the working fluid to cool an air flow 1118 directed across the heat exchanger 1116 to generate a cooled air flow 1120. The cooled air flow 1120 may be directed to the electronic equipment 1101 to cool the electronic equipment 1101.

Further, in some embodiments, the chiller system 1102 (e.g., working fluid circuit) may be configured to direct the working fluid to the electronic equipment 1101 to place the working fluid in a heat exchange relationship with the electronic equipment 1101. In such embodiments, the cooling system 1100 may not include the conditioning fluid circuit 1106 configured to circulate the conditioning fluid 1104 between the electronic equipment 1101 and the chiller system 1102. Rather, the conditioning fluid circuit 1106 shown in the illustrated embodiment may instead be a portion of the working fluid circuit configured to direct the working fluid to the electronic equipment 1101. Additionally or alternatively, the chiller system 1102 may be configured to direct the working fluid to the air handler 1114 to circulate the working fluid through the heat exchanger 1116 to generate the cooled air flow 1120. Accordingly, it should be appreciated that the techniques described herein may be incorporated with embodiments of the cooling system 1100 configured to supply the conditioning fluid 1104 (e.g., water, glycol) to the electronic equipment 1101, as well as embodiments of the cooling system 1100 configured to supply the working fluid (e.g., refrigerant) to the electronic equipment 1101.

In the illustrated embodiment, the electronic equipment 1101 includes a plurality of cabinets 1108, also referred to as racks, and each cabinet 1108 is configured to support a respective plurality of computer enclosures 1110. Each computer enclosure 1110 is configured to contain, house, and/or support one or more computer components, such as one or more server trays (e.g., server trays 104), integrated circuits, circuit boards, communication circuitry, processors, servers, memories, routers, switches, controllers, and/or other computer hardware. In some embodiments, one or more of the cabinets 1108 may be a computer server rack, a computer equipment rack, a server rack, a server chassis, or other suitable structure configured to support one or more of the computer enclosures 1110. The computer enclosures 1110 may include a rack server enclosure, a server tray enclosure, a blade server enclosure, another suitable enclosure configured to contain electronic components, or any combination thereof. The cabinets 1108 may be disposed within an embodiment of a building configured as a data center.

During operation, the electronic equipment 1101 may generate heat, which may cause a temperature of the computer components within and/or thermally coupled to the computer enclosures 1110 to increase. It is desirable to maintain the temperature of the computer components within and/or coupled to the computer enclosures 1110 below applicable temperature thresholds in order to enable proper operation of the computer components and avoid operational interruptions. Accordingly, present embodiments include the cooling system 1100 configured to supply working fluid and/or conditioning fluid to the cabinets 1108 and/or the computer enclosures 1110 to absorb heat generated by the computer components and reject the heat to another suitable location or environment.

As will be appreciated, some systems utilized to cool computer components may include an HVAC&R system having a working fluid circuit, a conditioning fluid circuit configured to circulate a conditioning fluid, and a coolant circuit configured to circulate a coolant. During operation of such systems, the working fluid circuit (e.g., refrigeration circuit 111) and the conditioning fluid circuit (e.g., primary coolant loop 120) may be in a heat exchange relationship to enable transfer of heat from the conditioning fluid to the working fluid, while the conditioning fluid circuit and the coolant circuit (e.g., secondary coolant loop 130) may be in a heat exchange relationship to enable transfer of heat from the coolant fluid to the conditioning fluid. For example, such systems may include a coolant distribution unit (CDU) (e.g., CDU 106) having a heat exchanger configured to establish a heat exchange relationship between the conditioning fluid circuit and the coolant circuit. The coolant circuit may extend from the CDU to the computer equipment to place the coolant in a heat exchange relationship with the computer equipment in order to absorb heat generated by the computer equipment.

Various embodiments of the cooling system 1100 do not include a CDU having a heat exchanger configured to place a conditioning fluid and a coolant in a heat exchange relationship. Present embodiments also may not include a separate coolant circuit in addition to the working fluid circuit of the HVAC&R system (e.g., chiller system 1102) and/or the conditioning fluid circuit 1106. Instead, the cooling system 1100 may include the conditioning fluid circuit 1106 extending from the chiller system 1102 (e.g., from the evaporator 1150 of the chiller system 1102) to the electronic equipment 1101 and configured to circulate the conditioning fluid 1104 between the chiller system 1102 (e.g., the evaporator 1150 of the chiller system 1102) and the electronic equipment 1101 (e.g., cabinets 1108, computer enclosures 1110). Thus, the conditioning fluid circuit 1106 may place the conditioning fluid 1104 in a heat exchange relationship with the working fluid circulated along the working fluid circuit and through the evaporator 1150 of the chiller system 1102, and the conditioning fluid circuit 1106 may also place the conditioning fluid 1104 in a heat exchange relationship with computer components disposed within and/or thermally coupled to the computer enclosures 1110. For example, the conditioning fluid circuit 1106 may include one or more flow paths that extend within the cabinets 1108 and/or within one or more of the computer enclosures 1110. In this way, a stage of heat transfer typically included in certain systems may be omitted, which may enable operation of the chiller system 1102 with reduced energy consumption.

While the illustrated embodiment includes the conditioning fluid circuit 1106 extending from the chiller system 1102 to the electronic equipment 1101 (e.g., cabinets 1108, computer enclosures 1110), other embodiments of the cooling system 1100 may not include the conditioning fluid circuit 1106, as mentioned above. Instead, the working fluid circuit of the chiller system 1102 may extend from the chiller system 1102 to the electronic equipment 1101 (e.g., cabinets 1108, computer enclosures 1110). The working fluid circuit may therefore operate to cool the working fluid and place the working fluid in a heat exchange relationship with the electronic equipment 1101 (e.g., computer components disposed within the computer enclosures 1110). For example, the working fluid may be circulated through the computer enclosure 1110, such as via a tube, conduit, flow path, channel, vessel, chilled plate, cold plate, immersion cooling techniques (e.g., direct contact with one or more computer components), or any combination thereof. In this way, a stage of heat transfer between the working fluid and a conditioning fluid may also be omitted, which may enable operation of the chiller system 1102 and the cooling system 1100 with further reduced energy consumption.

In some embodiments, the cooling system 1100 may also include a fluid distribution system 1112 configured to enable distribution of the conditioning fluid 1104 and/or the working fluid to the electronic equipment 1101 (e.g., to each cabinet 1108, to each computer enclosure 1110). The conditioning fluid circuit 1106 and/or the fluid distribution system 1112 may include one or more components, such as one or more pumps 1113, filters 1115, valves 1117, sensors 1119, bypass conduits, and so forth. For example, the fluid distribution system 1112 may include one or more sensors 1119 configured to detect a parameter indicative of a quality or characteristic of the working fluid and/or the conditioning fluid 1104 (e.g., particle concentration, chemical component) directed to the cabinets 1108 and/or computer enclosures 1110. In some embodiments, the fluid distribution system 1112 may include an in-line spectrometry sensor disposed along the working fluid circuit and/or the conditioning fluid circuit 1106. The fluid distribution system 1112 may include certain components associated with a respective one of the cabinets 1108. For example, the fluid distribution system 1112 may include multiple pumps 1113 and/or valves 1117, and each pump 1113 and/or valve 1117 may be associated with a respective one of the cabinets 1108. In this way, components of the fluid distribution system 1112 may be actuated to suspend flow of the working fluid and/or the conditioning fluid 1104 to one of the cabinets 1108, while enabling flow of the working fluid and/or the conditioning fluid 1104 to remaining cabinets 1108. In some embodiments, the fluid distribution system 1112 may be configured to regulate flow of a respective portion of the working fluid and/or the conditioning fluid 1104 to each computer enclosure 1110 disposed within the cabinet 1108.

In some embodiments, the fluid distribution system 1112 may include one or more filters 1115 (e.g., permeable membrane) configured to enable flow of the working fluid and/or the conditioning fluid 1104 therethrough and to capture one or more particles and/or contaminants within the flow of working fluid and/or conditioning fluid 1104. One or more of the components of the fluid distribution system 1112 may be contained in a dedicated housing or unit, distributed along the working fluid circuit and/or conditioning fluid circuit 1106 at other locations, integrated within one or more of the cabinets 1108, integrated with the chiller system 1102, or any combination thereof.

In some embodiments, a first portion 1105 of the conditioning fluid circuit 1106 may extend through the evaporator 1150 of the chiller system 1102, and a second portion 1107 of the conditioning fluid circuit 1106 may extend through one or more of the cabinets 1108. For example, the first portion 1105 of the conditioning fluid circuit 1106 may extend through tubes of the evaporator 1150 configured to place the conditioning fluid 1104 in a heat exchange relationship with a working fluid directed through a shell of the evaporator 1150. Alternatively, a portion of the working fluid circuit may extend through one or more of the cabinets 1108. The second portion of the conditioning fluid circuit 1106 and/or a portion of the working fluid circuit may be defined by any suitable component disposed within the cabinet 1108. For example, the second portion of the conditioning fluid circuit 1106 and/or a portion of the working fluid circuit may be at least partially defined by one or more of the computer enclosures 1110, a heat exchanger 1111 (e.g., cold plate) coupled to or disposed within one or more of the computer enclosures 1110, a heat exchanger 1111 (e.g., cold plate) disposed within the cabinet 1108, or any combination thereof. In any case, the second portion of the conditioning fluid circuit 1106 and/or a portion of the working fluid circuit may enable transfer of heat from within the cabinet 1108 to the conditioning fluid 1104 directed along the conditioning fluid circuit 1106 and/or to the working fluid directed along the working fluid circuit.

In accordance with embodiments of the present disclosure, a fluid (e.g., a conditioning fluid, a working fluid, a refrigerant, a two-phase fluid) of a data center cooling system may be biased toward at least one computer enclosure, such as a plurality of computer enclosures disposed in or otherwise integrated with one or more cabinets, also referred to as racks. In general, the fluid may extract heat from computer equipment (e.g., chip, server, etc.) in the at least one computer enclosure and/or from one or more cold plate(s) associated with the computer enclosure(s) and/or the computer equipment. In some embodiments, the fluid directly contacts the computer equipment and/or comes into close proximity to the computer equipment in order to establish a heat exchange relationship between the fluid and the computer equipment. In other embodiments, the fluid does not contact the computer equipment, but comes into close proximity to the computer equipment and contacts a cold plate associated with (e.g., operating as a heat sink for) the computer equipment.

Due to this contact and/or close proximity between the fluid and the computer equipment, it may be desirable to ensure that the fluid is pure and filtered of contaminants that could otherwise negatively affect the computer equipment and/or other aspects of the data center or data center cooling system. Accordingly, presently disclosed embodiments include a pump filtration system configured to filter the fluid upstream of the computer enclosure(s) and corresponding computer equipment and/or cold plate(s). For example, the pump filtration system may receive the fluid in a liquid form from a condenser configured to cool or subcool the fluid upstream of the pump filtration system. The pump filtration system may include a filter membrane, a motor, and an impeller rotated by the motor to bias the fluid in the liquid form, for example, through the filter membrane, such that contaminants (e.g., particles) are separated from the fluid in the liquid form by the filter membrane. The fluid in a filtered liquid form may be output from the pump filtration system toward the computer enclosure(s). It should be understood that the pump filtration system, described in greater detail below, may be employed in certain suitable embodiments corresponding to certain of the systems described above with respect to FIGS. 1-7. These and other aspects of the present disclosure are described in detail below with references to the drawings.

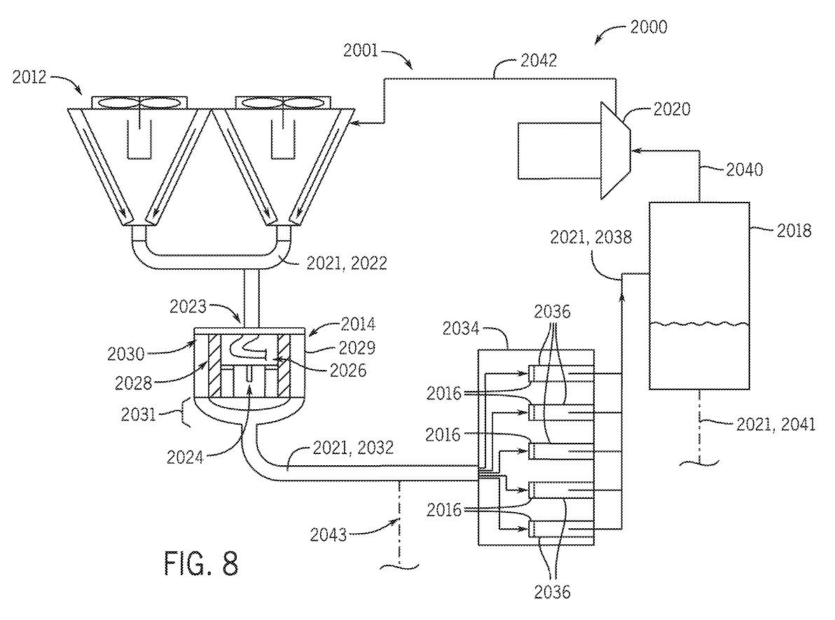

FIG. 8 is a schematic of an embodiment of a data center cooling system 2000 including a working fluid circuit 2001, a pump filtration system 2014, and a separator 2018, where the pump filtration system 2014 is configured to maintain a purity of a working fluid corresponding to the working fluid circuit 2001, and the separator 2018 is configured to manage various phases or forms of the working fluid. In addition to the working fluid circuit 2001, the pump filtration system 2014, and the separator 2018, the data center cooling system 2000 may include a condenser 2012, a plurality of expansion valves 2016, and a compressor 2020, among other possible componentry.

The condenser 2012 may output, toward the pump filtration system 2014, a working fluid 2021 in a liquid form 2022 (e.g., a subcooled liquid). In some embodiments, the condenser 2012 cools or subcools the working fluid 2021 in a gaseous or vapor form (described in greater detail below) to generate the working fluid 2021 in the liquid form 2022. That is, the working fluid 2021 in the liquid form 2022 may be a cooled or subcooled working fluid received by the pump filtration system 2014. The working fluid 2021 may include, for example, a two-phase refrigerant configured to changes phases, also referred to as forms, in various areas of the data center cooling system 2000.

The pump filtration system 2014, described in greater detail with reference to later drawings, may include an inlet 2023 (e.g., including or formed at least in part by a spiral volute or vortex line), a motor 2024, an impeller 2026, a filter membrane 2028, a liquid passage 2030, and a casing 2029 configured to receive and/or house at least the motor 2024, the impeller 2026, the filter membrane 2028, and the liquid passage 2030. In general, the pump filtration system 2014 is configured to filter the working fluid 2021 in the liquid form 2022 and output, via an outlet 2031 of the pump filtration system 2014 fluidly coupled with the liquid passage 2030, the working fluid 2021 in a filtered liquid form 2032 toward, for example, a cabinet 2034 (also referred to as a rack).

Because the filter membrane 2028 may act as a flow impediment, among other and/or alternate possible reasons, the motor 2024 and at least a portion of the impeller 2026 may coordinate to bias the working fluid 2021 in the liquid form 2022 through the filter membrane 2028, where the filter membrane 2028 extracts contaminants (e.g., contaminant particles of undesirable material constituents) from the working fluid 2021 in the liquid form 2022 to generate the working fluid 2021 in the filtered liquid form 2032. For example, the motor 2024 may operate to turn the impeller 2026, including blades thereof, where the blades bias (e.g., sweep) the working fluid 2021 in the liquid form 2022 through the filter membrane 2028 to generate the working fluid 2021 in the filtered liquid form 2032. The blades of the impeller 2026 are illustrated in, and described in greater detail with respect to, later drawings of the present disclosure. Further, as later described in greater detail with reference to later drawings, componentry of the pump filtration system 2014 may include annular configurations, such as a first annular configuration of the casing 2029, a second annular configuration of the filter membrane 2028, a third annular configuration of the liquid passage 2030, and a fourth annular configuration (e.g., fourth annular body configuration) of the impeller 2026 (or portion thereof). In other words, in certain embodiments of the present disclosure, the casing 2029 may be referred to as an annular casing, the filter membrane 2028 may be referred to as an annular filter membrane, the liquid passage 2030 may be referred to as an annular liquid passage (e.g., an annular outer liquid passage) between the annular casing and the annular filter membrane, and the impeller 2026 (or portion thereof) may be referred to as an annular impeller and/or an annular body of the impeller 2026 (e.g., disposed radially from the annular filter membrane).

The filter membrane 2028 may be a fine particle filter membrane, such as a 5 micron filter, a 10 micron filter, a 15 micron filter, a 20 micron filter, or a 25 micron filter. Further details regarding the pump filtration system 2014 will be provided with respect to later drawings. The working fluid 2021 in the filtered liquid form 2032 may be biased from the outlet 2031 of the pump filtration system 2014 toward the cabinet(s) 2034 as previously described. In some embodiments, the working fluid 2021 in the filtered liquid form 2032 is received into various computer enclosures 2036 housing computer equipment (e.g., chips, servers, etc.) therein, while in other embodiments, the working fluid 2021 in the filtered liquid form 2032 is received into one or more cold plates associated with the computer enclosures 2036. In some embodiments, the one or more expansion valves 2016 (e.g., electronic expansion valves or EEVs) may be employed at inlets and/or outlets of the computer enclosures 2036 (or cold plate(s) associated therewith) to control flow characteristics of the working fluid 2021 flowing into, through, and/or out of the computer enclosures 2036 (or cold plate(s) associated therewith). The working fluid 2021 in the filtered liquid form 2032 may extract heat from the computer enclosures 2036 and/or cold plate(s) to generate the working fluid 2021 in a gas, vapor, or mixed-phased form 2038. For example, the working fluid 2021 output from the rack(s) 2034 may include a low-pressure gas or mixed-phase fluid in certain embodiments of the present disclosure.

The working fluid 2021 in the gas, vapor, or mixed-phase form 2038 output from the rack(s) 2034 may be received by the separator 2018, as shown. The separator 2018 may be employed for one or more functions, such as separating a gas form 2040 of the working fluid 2021 from a liquid form of the working fluid 2021, where the working fluid 2021 in the gas form 2040 is output toward the compressor 2020. In some embodiments, a liquid return portion 2041 of the working fluid 2021 is output by the separator 2018 to another area of the data center cooling system 2000 or elsewhere. For example, the liquid return portion 2041 of the working fluid 2021 may be biased toward a return conduit 2043 such that the liquid return portion 2041 of the working fluid 2021 is routed (e.g., along with the working fluid 2021 in the filtered liquid form 2032 output by the pump filtration system 2014) back to the rack(s) 2034. However, the separator 2018 may serve additional and/or alternate functions in certain embodiments of the disclosure in addition to (or besides those) described above.

The working fluid 2021 in the gas form 2040 may be output from the separator 2018 to the compressor 2020, which operates to compress the working fluid in the gas form 2040 to generate an additional gas form 2042 of the working fluid 2021 biased toward the condenser 2012. For example, the working fluid 2021 in the additional gas form 2042 downstream from the compressor 2020 may include a higher pressure than the working fluid 2021 in the gas form 2040 upstream of the compressor 2020. In other words, the compressor 2020 may operate to increase a pressure of the working fluid 2021 and urge the working fluid 2021 from the separator 2018 to the condenser 2012. In some embodiments, the condenser 2012 includes condensing coils, at least one fan, and/or one or more expanders configured to condense and/or subcool the working fluid 2021 in the additional gas form 2042 to generate the working fluid 2021 in the liquid form 2022, which may be output toward the pump filtration system 2014, as previously described.

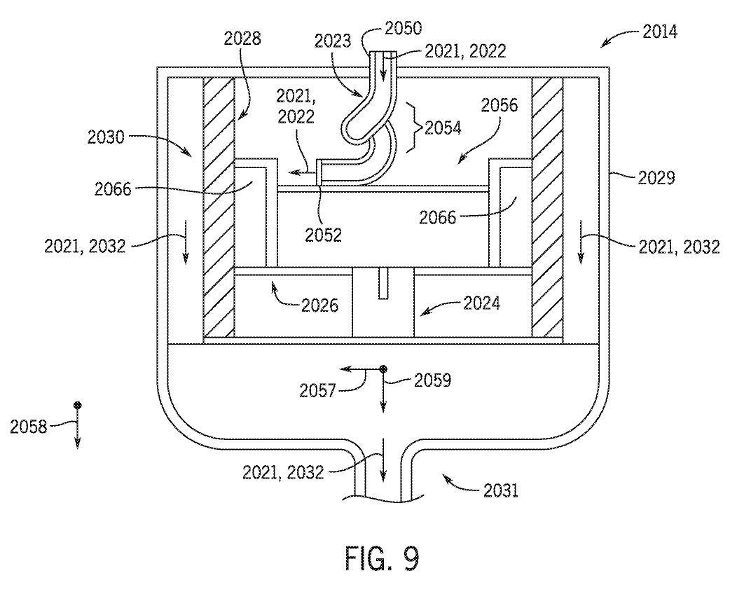

FIG. 9 is a cross-sectional schematic of an embodiment of a pump filtration system for a data center cooling system, such as the data center cooling system 2000 including the pump filtration system 2014 of FIG. 8. As previously described, the the pump filtration system 2014 may include the inlet 2023, the motor 2024, the impeller 2026, the filter membrane 2028, the casing 2029, the liquid passage 2030, and the outlet 2031, among other possible componentry. As shown, at least a portion of the inlet 2023, the motor 2024, the impeller 2026, the filter membrane 2028, and the liquid passage 2030 may be disposed in the casing 2029. The outlet 2031 may be at least partially disposed in and/or at least partially formed by the casing 2029.

In the illustrated embodiment, the inlet 2023 of the pump filtration system 2014 may include a spiral volute or vortex line having a first end 2050, a second end 2052 opposing the first end 2050, and a mid-section 2054 between the first end 2050 and the second end 2052. In some embodiments, the second end 2052 is disposed in and/or opens into a central cavity 2056 within the casing 2029. For example, the first end 2050 may be outside of the central cavity 2056 (and/or the casing 2029 as a whole), the second end 2052 may be within the central cavity 2056, and the mid-section may be at least partially within the central cavity 2056. In the illustrated embodiment, the second end 2052 of the inlet 2023 is oriented to cause the working fluid 2021 in the liquid form 2022 to be biased into the central cavity 2056 in a direction 2057 (e.g., radial direction) transverse to (e.g., perpendicular to) a gravity vector 2058. In other embodiments, the second end 2052 of the inlet 2023 may be oriented to cause the working fluid 2021 in the liquid form 2022 to be biased into the central cavity 2056 in an additional direction 2059 (e.g., axial direction) substantially parallel with the gravity vector 2058. Additional details regarding the first end 2050, the second end 2052, and the mid-section 2054 of the inlet 2023 (e.g., spiral volute) will be provided with respect to later drawings.

As shown, the impeller 2026 may include blades 2066 configured to bias (e.g., sweep) the working fluid 2021 in the liquid form 2022 from the central cavity 2056, toward and through the filter membrane 2028, and into the liquid passage 2030. In this way, the filter membrane 2028 may extract contaminant particles (e.g., particles of an undesirable material constituent) from the working fluid 2021 in the liquid form 2022 to generate the working fluid 2021 in the filtered liquid form 2032 received by the liquid passage 2030. In some embodiments, the blades 2066 extend through only a portion of a height of the central cavity 2056, while in other embodiments, the blades 2066 occupy substantially all of the height of the central cavity 2056. As shown, the liquid passage 2030 may be disposed between the filter membrane 2028 and one or more walls of the casing 2029 relative to the direction 2057 (e.g., radial direction) in certain embodiments of the present disclosure. In some embodiments, as shown in FIG. 9, the casing 2029 (or a portion thereof) includes a first annular configuration (e.g., a first annulus), the filter membrane 2028 includes a second annular configuration (e.g., a second annulus), the liquid passage 2030 includes a third annular configuration (e.g., a third annulus), and the impeller 2026 (or a portion thereof) includes a fourth annular configuration (e.g., a fourth annulus).

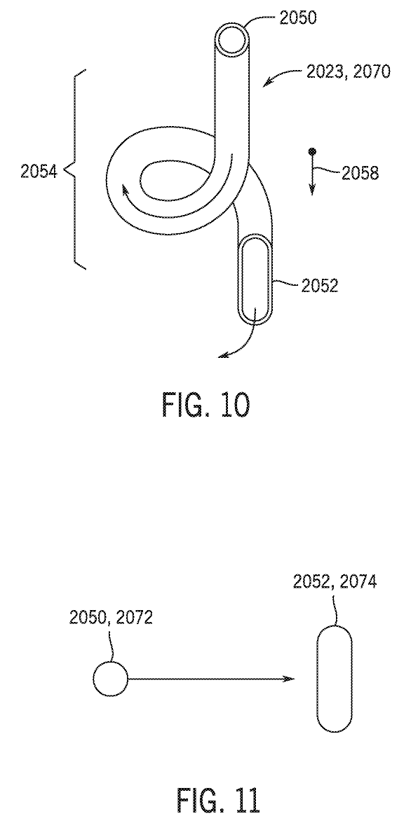

FIG. 10 is a perspective view of an embodiment of the inlet a spiral volute 2070 of a pump filtration system, such as the pump filtration system 2014 of FIG. 9, for a data center cooling system. The spiral volute 2070 may correspond to the inlet 2023 illustrated in FIGS. 8 and 9. As shown, the spiral volute 2070 in FIG. 10 includes the first end 2050, the second end 2052 opposing the first end 2050, and the mid-section 2054 between the first end 2050 and the second end 2052. FIG. 11 is a schematic of an embodiment of cross-sectional shapes of the first end 2050 and the second end 2052 of the spiral volute 2070 in FIG. 10. For example, a first cross-sectional shape 2072 at the first end 2050 of the spiral volute 2070 may include a circle, as shown in FIG. 11, and a second cross-section shape 2074 at the second end 2052 of the spiral volute 2070 may include an oval or oblong shape, as shown in FIG. 11. In some embodiments, a first orientation of the first cross-sectional shape 2072 of the first end 2050 of the spiral volute 2070 is oriented 90-degrees out of phase with a second orientation of the second cross-sectional shape 2074 of the second end 2052 of the spiral volute 2070. For example, the first cross-sectional shape 2072 of the first end 2050 may extend substantially perpendicular to the gravity vector 2058, and the second cross-sectional shape 2074 of the second end 2052 may extend substantially parallel with the gravity vector 2058. However, other orientations of the first end 2050 and the second end 2052 relative to each other and/or the gravity vector 2058 are also possible in accordance with the present disclosure.

As shown in FIG. 10, the mid-section 2054 may include a spiral configuration between the first end 2050 and the second end 2052 of the spiral volute 2070, along with a transition between the first cross-sectional shape 2072 of the first end 2050 illustrated in FIG. 11 and the second cross-sectional shape 2074 of the second end 2052 illustrated in FIG. 11. In general, the spiral volute 2070 is configured to manage and/or promote various desirable characteristics of the working fluid 2021 in the liquid form 2022 passing therethrough, where such desirable characteristics may include, as non-limiting examples, one or more desirable flow direction characteristics of the working fluid 2021 in the liquid form 2022, one or more desirable energy characteristics of the working fluid 2021 in the liquid form 2022, a desirable phase characteristic, temperature characteristic, and/or pressure characteristic of the working fluid 2021 in the liquid form 2022, one or more desirable velocity characteristics of the working fluid 2021 in the liquid form 2022, and/or one or more desirable acceleration characteristics of the working fluid 2021 in the liquid form 2022.

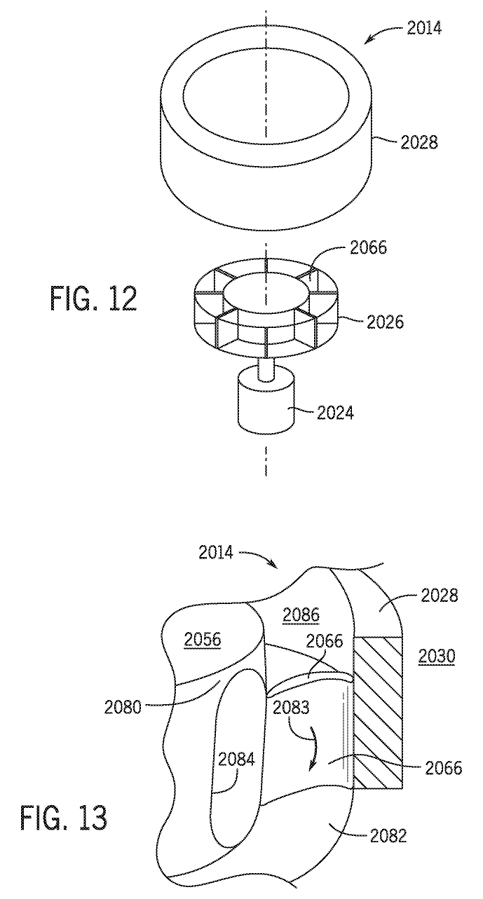

FIG. 12 is perspective view of an embodiment of a portion of a pump filtration system, 2014, such as the pump filtration system 2014 of FIG. 9, including the motor 2024 configured to turn the impeller 2026 such that the blades 2066 of the impeller 2026 motivate a fluid (e.g., a working fluid in liquid form) toward and through the filter membrane 2028. The filter membrane 2028 and the impeller 2026 (or a portion thereof) may include annular configurations in certain embodiments of the present disclosure, as shown in FIG. 12 and previously described with respect to earlier drawings. FIG. 13 is a perspective view of an embodiment of a portion of the pump filtration system 2014 including a wall 2080 (e.g., an annular wall, an annulus, an annular body), a ring 2082 (e.g., an annular ring, an annulus, an annular body, a disc) at least partially positioned between the wall 2080 and the filter membrane 2028, and the blades 2066 of the impeller 2026. For example, in certain embodiments, the ring 2082 is a part of the impeller 2026 and the blades 2066 are coupled to the ring 2082 and detached from the wall 2080. The motor 2024 of FIG. 12 may operate to turn the ring 2082 of FIG. 13 in such embodiments, thereby causing the ring 2082 and the blades 2066 coupled to the ring 2082 to turn in a circumferential direction 2083 to motivate the fluid (e.g., the working fluid in liquid form) toward and through the filter membrane 2028. The wall 2080 (e.g., an annular wall, an annulus) may include one or more openings 2084, as shown, through which the fluid (e.g., the working fluid in liquid form) passes, for example, from the central cavity 2056 toward the filter membrane 2028.

In other embodiments, the blades 2066 may be detached from the ring 2082 and instead coupled to the wall 2080, where the motor 2024 of FIG. 12 may operate to turn the wall 2080 of FIG. 13 instead of the ring 2082 of FIG. 13, thereby causing the wall 2080 and the blades 2066 coupled to the wall 2080 to turn in the circumferential direction 2083 to motive the fluid (e.g., the working fluid in liquid form) toward and through the filter membrane 2028. In other words, while certain embodiments may include rotation of the ring 2082 and the blades 2066 coupled thereto while the wall 2080 is stationary, other embodiments may include rotation of the wall 2080 and the blades 2066 coupled thereto while the ring 2082 is stationary. As previously described, the liquid passage 2030 (e.g., outer liquid passage) configured to receive the fluid (e.g., the working fluid in a filtered liquid form) from the filter membrane 2028 may be disposed radially outward from the filter membrane 2028. In certain embodiments, an additional liquid passage 2086 (e.g., inner liquid passage), also referred to as a space, is positioned between the wall 2080 and the filter membrane 2028. For example, the additional liquid passage 2086 may be aligned with the ring 2082. The liquid passage 2030, the additional liquid passage 2086, or both may include an annular configuration in certain embodiments of the present disclosure. Further, the blades 2066 may be disposed in an annular arrangement, and may include curvilinear shapes configured to motivate the fluid in the liquid form toward and through the filter membrane 2028.

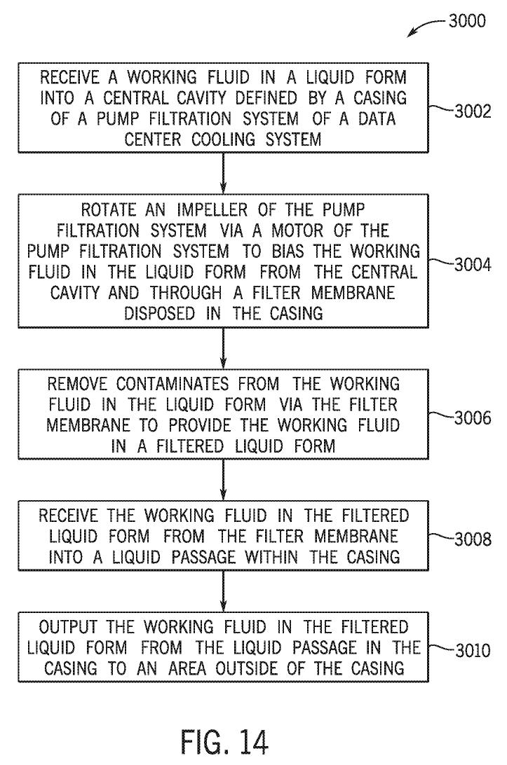

FIG. 14 is a process flow diagram illustrating an embodiment of a method 3000 of operating a data center cooling system including a pump filtration system. It should be noted that, while certain embodiments of the method 3000 may include performing the steps illustrated in FIG. 14 and described in detail below in the order they are presented, other embodiments of the method 3000 may include performing the steps in a different suitable order. Further, while certain embodiments of the method 3000 may include only the steps illustrated in FIG. 14 and described in detail below, other embodiments of the method 3000 may include additional steps or exclude certain steps illustrated in FIG. 14 and described in detail below.

In the illustrated embodiment, the method 3000 includes receiving (block 3002) a working fluid in a liquid form into a central cavity defined by a casing of a pump filtration system of the data center cooling system. For example, the working fluid in the liquid form may be received into the central cavity from a condenser. In some embodiments, the working fluid in the liquid form is received into the central cavity via spiral volute corresponding to an inlet of the pump filtration system.

The method 3000 also includes rotating (block 3004) an impeller of the pump filtration system via a motor of the pump filtration system to bias the working fluid in the liquid form from the central cavity and through a filter membrane disposed in the casing. For example, the impeller may include a plurality of blades configured to bias (e.g., sweep) the working fluid in the liquid form toward and through the filter membrane. The method 3000 also includes removing (block 3006) contaminants from the working fluid in the liquid form via the filter membrane to provide the working fluid in a filtered liquid form. The filter membrane may include, for example, a 5 micron filter, a 10 micron filter, a 15 micron filter, a 20 micron filter, or a 25 micron filter. The method 3000 also includes receiving (block 3008) the working fluid in the filtered liquid form from the filter membrane into a liquid passage within the casing, and outputting (block 3010) the working fluid in the filtered liquid form from the liquid passage in the casing to an area outside of the casing (e.g., from an outlet of the pump filtration system and/or into a conduit between the pump filtration system and one or more racks in which one or more computer enclosures and/or cold plates are disposed or otherwise integrated). In some embodiments, the method 3000 also includes extracting heat from the computer enclosure(s), the computer equipment therein, and/or the cold plate(s) associated therewith, such that the filtered liquid form of the working fluid is transformed to a gas, vapor, or mixed-phase form of the working fluid. In some embodiments, the method 3000 also includes biasing the working fluid from the rack(s) and through a separator, a compressor, or both. In some embodiments, the method 3000 also includes condensing the working fluid via a condenser to generate the working fluid in the liquid form (e.g., cooled or subcooled liquid) received by the pump filtration system.

While only certain features and embodiments have been illustrated and described, many modifications and changes may occur to those skilled in the art, such as variations in sizes, dimensions, structures, shapes and proportions of the various elements, values of parameters, such as temperatures and pressures, mounting arrangements, use of materials, colors, orientations, and so forth, without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

1. A data center cooling system comprising:
a condenser configured to output a working fluid in a liquid form;
a pump filtration system comprising:
a casing;
an inlet configured to receive the working fluid in the liquid form into the casing;
a filter membrane disposed in the casing;
a liquid passage between the casing and the filter membrane;
an impeller;
a motor configured to turn the impeller to bias the working fluid in the liquid form through the filter membrane to provide the working fluid in a filtered liquid form into the liquid passage; and
an outlet configured to output the working fluid in the filtered liquid form from the liquid passage.

2. The data center cooling system of claim 1, wherein the inlet comprises a spiral volute configured to output the working fluid in the liquid form into a central cavity of the pump filtration system.

3. The data center cooling system of claim 2, wherein the spiral volute comprises a first end, a second end opposing the first end and disposed in the central cavity, and a mid-section between the first end and the second end, the spiral volute is configured to guide the working fluid in the liquid form from the first end, through the mid-section, and to the second end, the first end comprises a first cross-sectional shape, the second end comprises a second cross-sectional shape different than the first cross-sectional shape, and the mid-section comprises a transition from the first cross-sectional shape to the second cross-sectional shape.

4. The data center cooling system of claim 3, wherein the first cross-sectional shape is a circle and the second cross-sectional shape is an oblong shape.

5. The data center cooling system of claim 1, comprising at least one cabinet configured to receive a plurality of computer enclosures, wherein the outlet of the pump filtration system is configured to output the working fluid in the filtered liquid form from the liquid passage toward the at least one cabinet.

6. The data center cooling system of claim 5, wherein each computer enclosure of the plurality of computer enclosures is configured to receive the working fluid in the filtered liquid form therein.

7. The data center cooling system of claim 5, comprising at least one cold plate corresponding to the at least one cabinet, wherein the at least one cold plate is configured to receive the working fluid in the filtered liquid form therein.

8. The data center cooling system of claim 5, comprising a separator disposed downstream from the at least one cabinet, wherein the separator is configured to separate a gas or vapor form of the working fluid from the filtered liquid form of the working fluid.

9. The data center cooling system of claim 5, comprising a compressor disposed downstream from the at least one cabinet, wherein the compressor is configured to increase a pressure of the working fluid in a gas or vapor form and bias the working fluid in the gas or vapor form toward the condenser.

10. The data center cooling system of claim 5, comprising a plurality of expansion valves corresponding to the plurality of computer enclosures.

11. The data center cooling system of claim 1, wherein:
the casing comprises a first annular configuration;
the filter membrane comprises a second annular configuration;
the liquid passage comprises a third annular configuration; and
the impeller comprises a fourth annular body configuration and a plurality of blades coupled to the fourth annular body configuration, wherein the motor is configured to turn the fourth annular body configuration.

12. The data center cooling system of claim 11, wherein each blade of the plurality of blades comprises a curvilinear shape.

13. A pump filtration system for a data center cooling system, the pump filtration system comprising:
an annular casing;
an inlet configured to receive a working fluid in a liquid form into the annular casing;
an annular filter membrane disposed in the annular casing;
an annular outer liquid passage between the annular casing and the annular filter membrane;
an impeller comprising an annular body disposed radially inward from the annular filter membrane;
a motor configured to turn the impeller to bias the working fluid in the liquid form through the annular filter membrane to provide the working fluid in a filtered liquid form into the annular outer liquid passage; and
an outlet configured to output the working fluid in the filtered liquid form from the annular outer liquid passage.

14. The pump filtration system of claim 13, wherein the inlet comprises a spiral volute configured to output the working fluid in the liquid form into a central cavity of the pump filtration system, and the annular filter membrane is disposed between the central cavity and the annular outer liquid passage.

15. The pump filtration system of claim 14, wherein the spiral volute comprises a first end, a second end opposing the first end and disposed in the central cavity, and a mid-section between the first end and the second end, the spiral volute is configured to guide the working fluid in the liquid form from the first end, through the mid-section, and to the second end, the first end comprises a first cross-sectional shape, the second end comprises a second cross-sectional shape different than the first cross-sectional shape, and the mid-section comprises a transition from the first cross-sectional shape to the second cross-sectional shape.

16. The pump filtration system of claim 15, wherein the first cross-sectional shape is a circle and the second cross-sectional shape is an oblong shape.

17. The pump filtration system of claim 15, comprising:
a wall with at least one opening therethrough;
a ring disposed between the wall and the filter membrane, wherein the wall or the ring corresponds to the annular body of the impeller; and
a plurality of blades coupled to the annular body, wherein the plurality of blades is configured to sweep a space between the wall and the filter membrane in response to the motor turning the annular body of the impeller to motivate the working fluid in the liquid form through the at least one opening in the wall, through the space, and toward the filter membrane.

18. The pump filtration system of claim 17, wherein each blade of the plurality of blades comprises a curvilinear shape.

19. A method of operating a data center cooling system, the method comprising:
receiving a working fluid in a liquid form into a central cavity defined by a casing of a pump filtration system of the data center cooling system;
rotating an impeller of the pump filtration system via a motor of the pump filtration system to bias the working fluid in the liquid form from the central cavity and through a filter membrane disposed in the casing;
removing contaminants from the working fluid in the liquid form via the filter membrane to provide the working fluid in a filtered liquid form;
receiving the working fluid in the filtered liquid form from the filter membrane into a liquid passage within the casing; and
outputting the working fluid in the filtered liquid form from the liquid passage in the casing to an area outside of the casing.

20. The method of claim 19, comprising receiving the working fluid in the liquid form into the central cavity via a spiral volute of the pump filtration system.
